(19) United States
(12) Patent Application Publication
(10) Pub. No.: US 2012/0076936 A1
(43) Pub. Date: Mar. 29, 2012

(54) SUBSTRATE PROCESSING APPARATUS, GAS NOZZLE AND METHOD OF PROCESSING SUBSTRATE

(75) Inventor: Makoto HIRANO, Toyama (JP)

(73) Assignee: HITACHI KOKUSAI ELECTRIC INC., Tokyo (JP)

(21) Appl. No.: 13/209,515

(22) Filed: Aug. 15, 2011

(30) Foreign Application Priority Data
Sep. 24, 2010 (JP) 2010-213137

(51) Int. Cl. C23C 16/455; C23C 16/458

(52) U.S. Cl. 427/248.1; 118/724

(57) ABSTRACT

Provided are a substrate processing apparatus, a gas nozzle, and a method of processing a substrate, which is capable of improving heating efficiency of a gas without increasing a size of a reaction container. A gas supply nozzle 300 includes a first extension part 321, a third extension part 323, and a fifth extension part 325, which extend in a circumferential direction of wafers 200, and the first extension part 321, a second extension part 322, a fourth extension part 324, and a sixth extension part 326, which extend in a stacking direction of the wafers 200. The gas supply nozzle 300 may be disposed in a gap between an outer tube and an inner tube to save a space without increasing a size of a processing furnace as in the art. By increasing a gas circulation path of the gas supply nozzle 300, a gas in the gas supply nozzle 300 can be sufficiently heated due to radiant heat of each susceptor 218. As a result, the heating efficiency of the gas can be improved and thus, the occurrence of slip or haze on each of the wafers 200 can be suppressed.

### CROSS-REFERENCE TO RELATED PATENT APPLICATION

This U.S. non-provisional patent application claims priority under 35 U.S.C. §119 of Japanese Patent Application No. 2010-213137, filed on Sep. 24, 2010 in the Japanese Patent Office, the entire contents of which are hereby incorporated by reference.

### BACKGROUND OF THE INVENTION

1. Field of the Invention

The present invention relates to a substrate processing apparatus, a gas nozzle and a method of processing a substrate.

2. Description of the Related Art

For example, techniques described in Patent Documents 1 through 3 are known as a conventional substrate processing apparatus using chemical vapor deposition (CVD) for a semiconductor or solar cell.

Patent Document 1 describes a technique of fabricating a semiconductor device including forming a boron-doped silicon film on a substrate using a CVD method in a reaction furnace using monosilane (SiH₄) and boron trichloride (BCl₃) as reactive gases. A return nozzle folded in a U shape to reciprocate between lower and upper portions of a boat in the reaction furnace is used as a gas nozzle for supplying a reactive gas toward the boat in the reaction container to supply the BCl₃ through the return nozzle. Due to the return nozzle, a heating of the BCl₃ in the reaction furnace may be increased and furthermore, decomposition of the BCl₃ may be promoted, thereby improving film-forming precision.

Patent Document 2 describes a technique in which an oxidation gas line configured to supply an oxidation gas (e.g., H₂ or O₂) to a boat in a reaction container is separated from a gettering gas line for supplying a gettering gas (HCl or dichloroethene (DCE)) to the boat in the reaction container and a return nozzle is used as a gettering gas introduction nozzle (or gas nozzle). Since the return nozzle is used as the gettering gas introduction nozzle, a temperature of the gettering gas may be sufficiently raised during introduction of a gas into a wafer (or substrate), thereby improving film-thickness uniformity between wafers.

Patent Document 3 describes a technique related to a substrate processing apparatus including a heated body for heating a substrate and a gas introduction nozzle (or gas nozzle) for supplying a gas into a reaction container, in which a channel section (e.g., channel area) of at least a portion of the gas introduction nozzle disposed opposite the heated body is increased more than that of other portions thereof and the temperature of a gas flowing through at least the portion is raised. By increasing the channel section of the portion of the gas introduction nozzle disposed opposite the heated body, even if a film-forming reaction occurs in the portion, clogging of the gas introduction nozzle is suppressed, thus facilitating reduction in maintenance work.

### RELATED ART DOCUMENT

### Patent Document

[Patent Document 1] Japanese Unexamined Patent Application Publication No. 2003-178992
[Patent Document 2] Japanese Unexamined Patent Application Publication No. 2005-277286
[Patent Document 3] Pamphlet of International Patent Publication No. WO2005/015619

However, according to the above-described techniques described in Patent Documents 1 and 2, since a direction in which the return nozzle is folded follows a radial direction of the boat (or wafer), a dimension of the return nozzle in the radial direction of the boat may be increased, and the reaction furnace (or reaction container) may be large. Also, to further raise a temperature of a gas in the return nozzle, it may be necessary to increase the number of times the return nozzle is folded. In this case, the dimension of the return nozzle in the radial direction of the boat may be further increased, and a larger reaction furnace corresponding to the dimension of the return nozzle may be required. Furthermore, in the substrate processing apparatus described in Patent Document 3, since a temperature of a gas is raised using a straight-type gas introduction nozzle right before a gas jet hole, an output of a heated body should be necessarily increased to sufficiently raise the temperature of the gas, thereby causing poor gas heating efficiency.

### SUMMARY OF THE INVENTION

It is an object of the present invention to provide a substrate processing apparatus, a gas nozzle and a method of processing a substrate, which are able to improve heating efficiency of a gas in a nozzle without increasing the size of a reaction container.

The above or other objects and novel features of the present invention will be apparent from the detailed description of the invention with reference to the following drawings.

Summaries of representatives of the present invention described herein will be described below in brief.

That is, a substrate processing apparatus according to the present invention includes a reaction container configured to process a plurality of substrates stacked in a substrate holder; a heated body configured to heat an inside of the reaction container; and a gas nozzle installed in the reaction container, and including a first pipe extending in a circumferential direction of the plurality of substrates and a second pipe including a gas supply hole wherethrough a gas supplied from an outside of the reaction container is supplied in a horizontal direction with respect to each of the plurality of substrates stacked on the substrate holder, the second pipe extending in a stacking direction of the plurality of substrates and having a first end connected to a first end of the first pipe.

Effects obtained by the representatives of the present invention will be described below in brief.

That is, the heating efficiency of the gas in a nozzle may be improved without increasing the size of the reaction container.

### BRIEF DESCRIPTION OF THE DRAWINGS

FIG. 1 is a perspective view illustrating a schematic configuration of a substrate processing apparatus according to the present invention.

FIG. 2 is a top view of a susceptor holding a wafer.

FIG. 3 is a cross-sectional view taken along line A-A′ of FIG. 2.

FIG. 4 is a cross-sectional view of a wafer separated from the susceptor.

FIG. 5 is a lateral view of an entire structure of a boat.

FIG. 6 is a top view of a boat in which the susceptor holding the wafer is loaded.

FIG. 7 is a cross-sectional view taken along line B-B of FIG. 6.

FIG. 8 is a schematic cross-sectional view of a processing furnace of a substrate processing apparatus and a periphery of the processing furnace according to a first embodiment of the present invention.

FIG. 9 is a longitudinal cross-sectional view illustrating a longitudinal section of the processing furnace of FIG. 8.

FIG. 10 is an enlarged cross-sectional view of a dotted circle C of FIG. 9.

FIG. 11 is a perspective view showing a positional relationship between a gas supply nozzle and a wafer according to a first embodiment.

FIG. 12 is a lateral view of a detailed construction of the gas supply nozzle of FIG. 11.

FIG. 13 is a diagram for explaining a pipe length of each portion of the gas supply nozzle of FIG. 12.

FIG. 14 is a timing chart showing a processing sequence of the substrate processing apparatus.

FIG. 15 is a longitudinal cross-sectional view illustrating a longitudinal section of a processing furnace of a substrate processing apparatus according to a second embodiment.

FIG. 16 is a perspective view illustrating a configuration of an inner tube of a substrate processing apparatus according to a third embodiment.

FIG. 17 is a longitudinal cross-sectional view illustrating a longitudinal section of a processing furnace of a substrate processing apparatus according to a fourth embodiment.

FIG. 18 is a longitudinal cross-sectional view illustrating a longitudinal section of a processing furnace of a substrate processing apparatus according to a fifth embodiment.

FIG. 19 is a perspective view showing a positional relationship between a gas supply nozzle and a wafer according to the fifth embodiment.

FIG. 20 is a lateral view of a detailed structure of the gas supply nozzle of FIG. 19.

FIG. 21 is a diagram for explaining a pipe length of each portion of the gas supply nozzle of FIG. 20.

### DETAILED DESCRIPTION OF THE PREFERRED EMBODIMENTS

The following embodiments are divided into a plurality of sections or embodiments, when necessary for the sake of convenience. Therefore, unless clearly indicated otherwise, the divided sections or embodiments are not irrelevant to one another, but one section or embodiment has a relation of modifications, details and supplementary explanations to some or all of the other embodiments.

In addition, in the following embodiments, when the number (including count, figure, amount, and range) of components is mentioned, the number of the components is not limited to a specific number and may be greater than, less than or equal to the specific number, unless clearly specified otherwise and definitely limited to the specific number in principle.

Furthermore, there is no need to say that, in the following embodiments, the components (including component steps, etc.) are not always essential, unless clearly specified otherwise and considered to be definitely essential in principle.

Similarly, when shapes and positional relationships, etc. of the components are mentioned in the following embodiments, the components will have shapes substantially analogous or similar to their shapes or the like, unless clearly defined otherwise and considered not to be definite in principle. This is applied likewise to the above-described numerical values and ranges as well.

In addition, in all the drawings for explaining the embodiments, the same components are indicated by the same reference numerals in principle, and so a repeated description thereof will be omitted. Also, hatching may be used even in plan views to make it easy to read the drawings.

### First Embodiment

In embodiments for carrying out the present invention, a substrate processing apparatus is configured, for example, as a semiconductor fabrication apparatus for performing various processing operations included in a method of fabricating, for example, a semiconductor device (e.g., an integrated circuit (IC)). In the following description, a vertical substrate processing apparatus for forming a film using an epitaxial growth process, forming a film using a chemical vapor deposition (CVD) process, or performing an oxidation process or diffusion process on a semiconductor substrate (or semiconductor wafer) to which the technical idea of the present invention is applied will be described. In particular, in this embodiment, a batch-type substrate processing apparatus for processing a plurality of substrates at once will be described.

<Construction of Substrate Processing Apparatus>

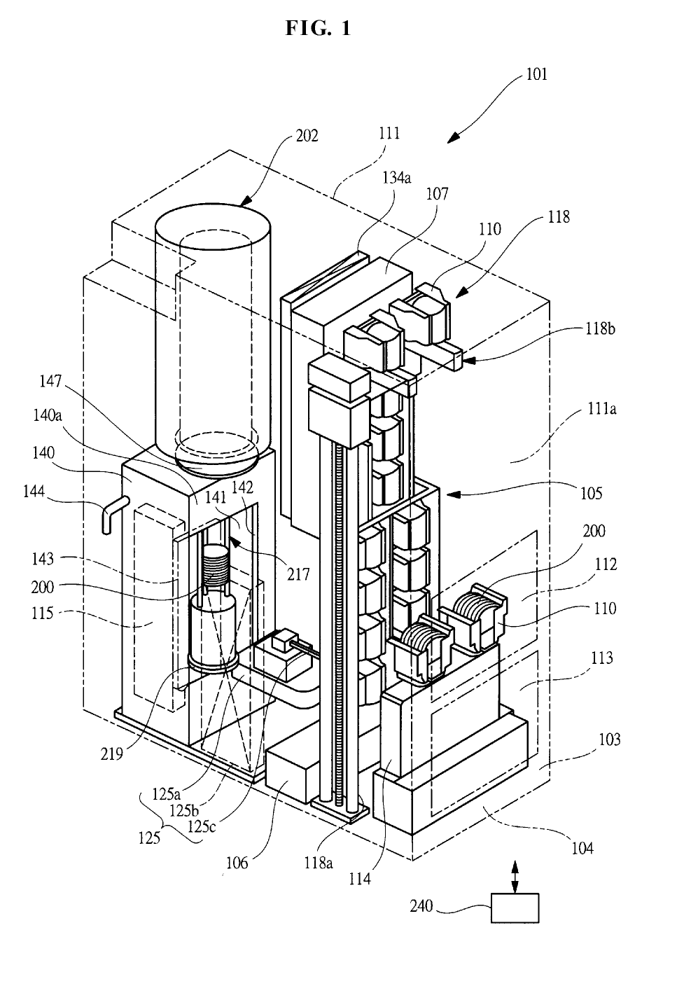

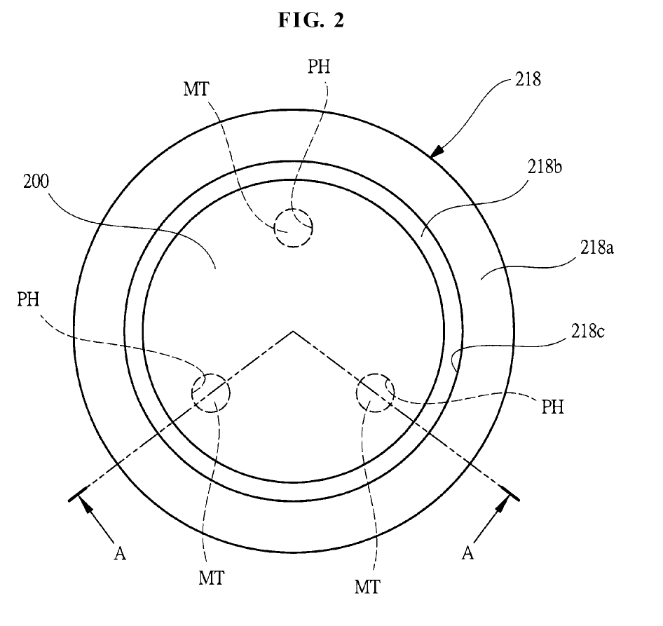

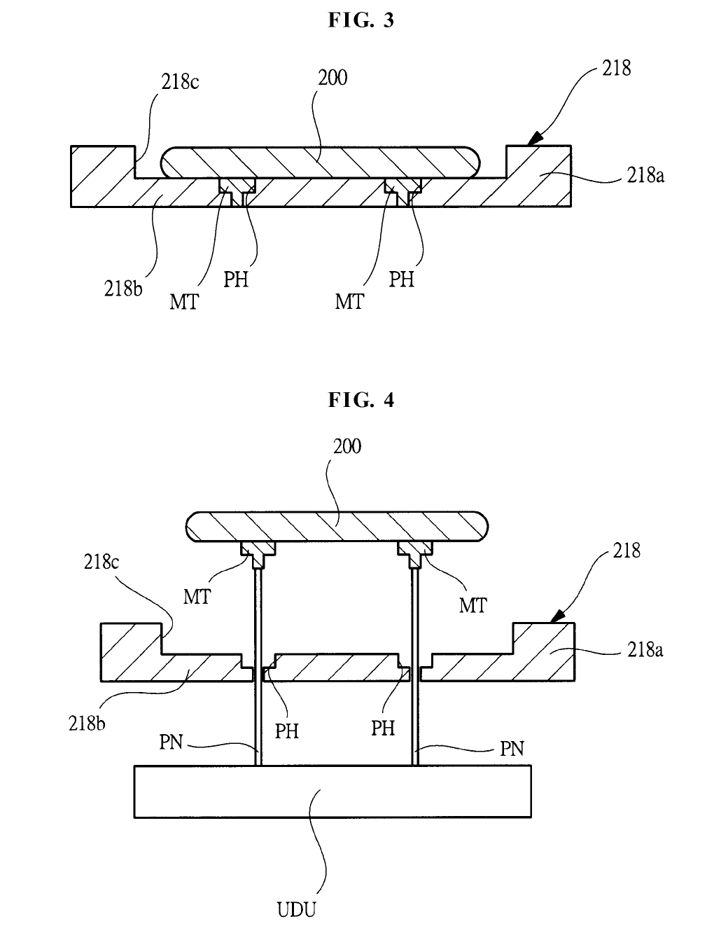

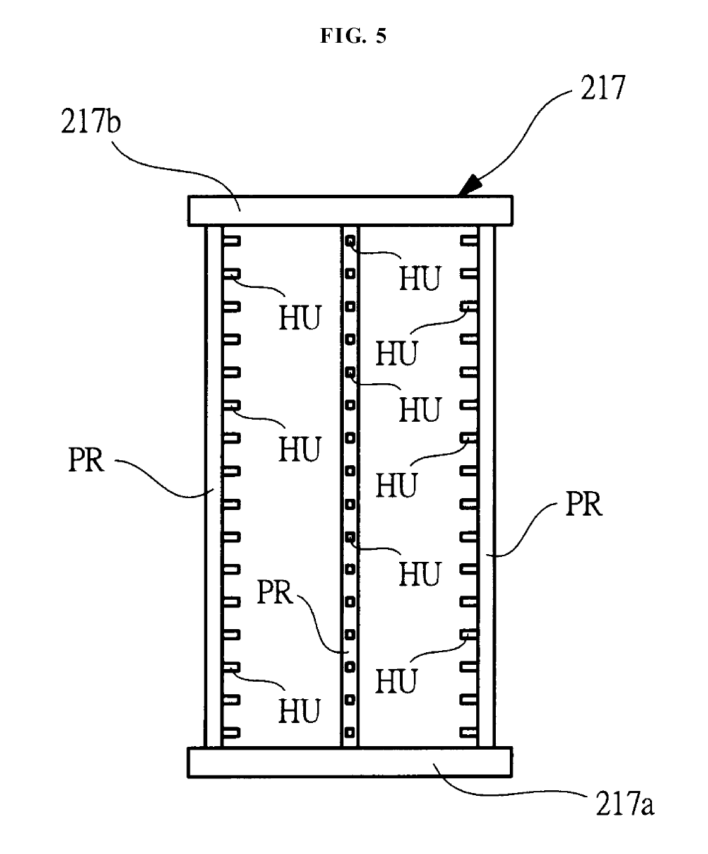

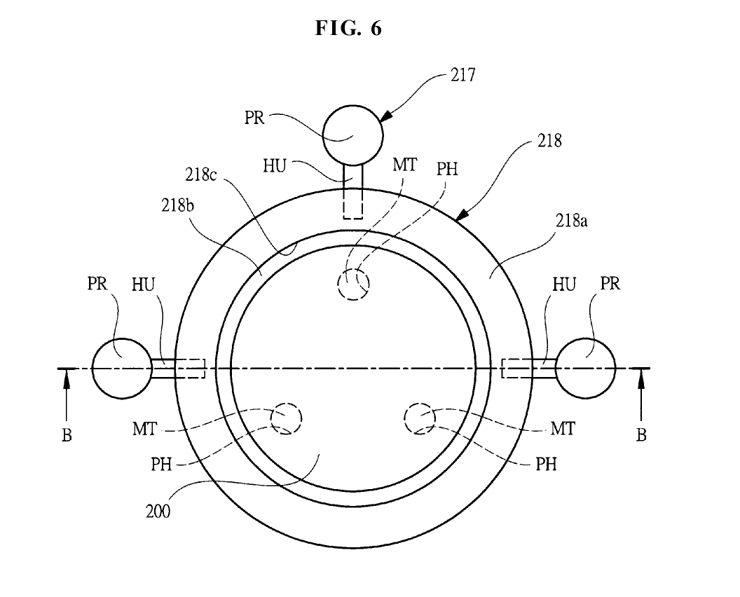

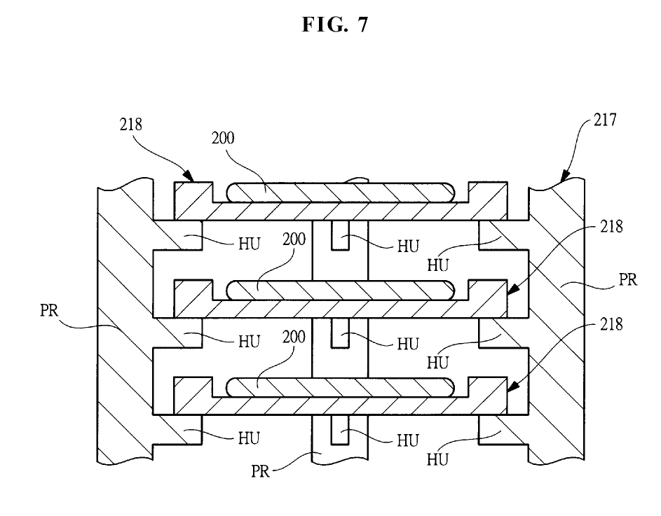

To begin with, a substrate processing apparatus according to a first embodiment will be described with reference to the drawings. FIG. 1 is a perspective view illustrating a schematic configuration of a substrate processing apparatus according to the present invention. FIG. 2 is a top view of a susceptor holding a wafer. FIG. 3 is a cross-sectional view taken along line A-A′ of FIG. 2. FIG. 4 is a cross-sectional view of a wafer separated from the susceptor. FIG. 5 is a lateral view of an entire structure of a boat. FIG. 6 is a top view of a boat in which the susceptor holding the wafer is loaded. FIG. 7 is a cross-sectional view taken along line B-B of FIG. 6.

Hereinafter, respective members constituting the substrate processing apparatus 101 will be described on the assumption that a lateral surface of a housing 111 with respect to which the cassette 110 is loaded and unloaded is a front surface thereof. Also, positions of respective members of the housing 111 will be described on the assumption that a direction toward the front surface is a forward direction and a direction away from the front surface is a backward direction.

As shown in FIG. 1, a substrate processing apparatus 101 includes a cassette 110 serving as a wafer carrier, and a plurality of wafers 200 (or substrates) serving as semiconductor substrates formed of silicon are accommodated in the cassette 110. The housing 111 forming an outer portion of the substrate processing apparatus 101 has, for example, a rectangular shape, and the cassette 110 is loaded and unloaded with respect to an inside of the housing 111. As an opening for maintaining the substrate processing apparatus 101, a front maintenance hole 103 is installed in a lower portion of a front wall 111a of the housing 111, and the front maintenance hole 103 may be opened and closed by a front maintenance door 104 installed at the front wall 111a of the housing 111.

A cassette loading/unloading hole (or a substrate-container loading/unloading hole) 112 is installed at the front maintenance door 104 to communicate between inside and outside of the housing 111. The cassette loading/unloading hole 112 may be opened and closed by a front shutter (or a substrate-container loading/unloading hole opening/closing mechanism) 113. A cassette stage (or a substrate container transfer stage) 114 is installed inside the housing 111 of the cassette loading/unloading hole 112. The cassette 110 is loaded onto the cassette stage 114 by an in-process conveyance apparatus (not shown) and unloaded from the cassette stage 114. The cassette 110 is placed on the cassette stage 114 by the in-process conveyance apparatus so that the wafer 200 of the cassette 110 is positioned in a vertical posture and a wafer entrance hole faces upward.

The casing 111 has a cassette shelf (or a substrate container placement shelf) 105 installed at approximately a lower center thereof in a longitudinal direction. The cassette shelf 105 stocks a plurality of cassettes 110 arranged in a plurality of stages and a plurality of columns, and is disposed to move the wafers 200 into or from the cassettes 110. The cassette shelf 105 is installed on a slide stage (or a horizontal moving mechanism) 106 to be movable in a lateral direction. Also, a buffer shelf (or a substrate container stocking shelf) 107 is installed above the cassette shelf 105, and the cassettes 110 are also stocked on the buffer shelf 107.

A cassette conveyance apparatus (or a substrate container conveyance apparatus) 118 is installed between the cassette stage 114 and the cassette shelf 105. The cassette conveyance apparatus 118 includes a cassette elevator (or a substrate container elevating mechanism) 118a capable of raising and lowering the cassettes 110 held thereby and a cassette conveyance mechanism (or a substrate container conveyance mechanism) 118b serving as a conveyance mechanism. Due to sequential operations of the cassette elevator 118a and the cassette conveyance mechanism 118b, the cassettes 110 may be conveyed among the cassette stage 114, the cassette shelf 105, and the buffer shelf 107.

A wafer transfer mechanism (or a substrate transfer mechanism) 125 is installed behind the cassette shelf 105. The wafer transfer mechanism 125 includes a wafer transfer apparatus (or a substrate transfer apparatus) 125a capable of rotating the wafer 100 in a horizontal direction and allowing the wafer 100 to move in a vertical direction, and a wafer transfer apparatus elevator (or a substrate transfer apparatus elevating mechanism) 125b for raising and lowering the substrate transfer apparatus 125a. As schematically shown in FIG. 1, the wafer transfer apparatus elevator 125b is installed in a right portion facing the front of the housing 111. Due to sequential operations of the wafer transfer apparatus elevator 125b and the wafer transfer apparatus 125a, tweezers (or a substrate holding hole) 125c installed at the wafer transfer apparatus 125a charge and discharge the wafer 200 with respect to the susceptor 218 (refer to FIG. 2) disposed in a susceptor holding mechanism (not shown) of the substrate processing apparatus 101.

As shown in FIGS. 2 and 3, the susceptor 218 is formed in a disk shape and includes an annular peripheral portion 218a and a circular central portion 218b. A thickness dimension of the peripheral portion 218a is set to be approximately twice a thickness dimension of the central portion 218b, and a stepped portion 218c is formed between the peripheral portion 218a and the central portion 218b. That is, the central portion 218b of the susceptor 218 has a concave shape. A disk-shaped wafer 200 is held by the central portion 218b to conform with an axial center of the central portion 218b due to an operation of tweezers 125c of a wafer transfer mechanism 125. An annular gap is formed between an outer circumferential side of the wafer 200 and an inner circumferential side of the peripheral portion 218a, and a diameter dimension of the wafer 200 becomes smaller than that of the central portion 218b. Also, a thickness dimension of the wafer 200 is set to be approximately equal to that of the central portion 218b. Thus, the wafer 200 is approximately hidden by the peripheral portion 218a when viewed from a lateral view of the susceptor 218.

Three pinholes PH, each of which is formed in a rough T shape (or flange shape), are installed at the central portion 218b of the susceptor 218. The three pinholes PH are installed at (regular) intervals of 60° along a circumferential direction of the central portion 218b. However, the number of pinholes PH is not limited to 3 and four or more pinholes PH may be installed. A support member MT for supporting the wafer 200 during separation of the wafer 200 from the susceptor 218 is installed in each of the pinholes PH. The support member MT is formed in a rough T shape like each of the pinholes PH and may be attached or detached with respect to each of the pinholes PH in an upward direction of FIG. 3. Here, each of the support members MT and each of the pinholes PH is formed in a flange shape, thereby preventing detachment of each of the support members MT in a downward direction of FIG. 3.

The susceptor 218 is used to heat the wafer 200 and its peripheral atmosphere (or the inside of the processing furnace 202) and constitutes a heated body according to the present invention. The susceptor 218 is formed of a conductive material (e.g., carbon or carbon graphite) whose surface is coated with silicon carbide (SiC). Since the surface of the susceptor 218 is coated with SiC, diffusion of impurities into the conductive material serving as a parent material of the susceptor 218 is inhibited. Here, although the susceptor 218 is preferably formed in a disk shape to uniformly heat an entire region of the disk-type wafer 200, the susceptor 218 may be formed in an elliptical or polygonal (e.g., regular hexahedral) shape. Also, although an outer circumferential side of the peripheral portion 218a of the susceptor 218 may have a roughly right-angled portion as shown in FIG. 3, the present invention is not limited thereto and the outer circumferential side of the peripheral portion 218a may have an arc sectional shape or an acute-angled sectional shape. In this case, some merits may be obtained. For example, a gas supplied in a horizontal direction of the susceptor 218 may be easily introduced to the wafer 200.

As shown in FIG. 4, an elevation-pin elevating mechanism UDU is installed at the susceptor holding mechanism of the substrate processing apparatus 101 and includes three elevation pins PN (only two elevation pins PN are shown). Each of the elevation pins PN is used to separate the wafer 200 from the susceptor 218 and raised and lowered by the elevation-pin elevating mechanism UDU. A specific operation of the elevation-pin elevating mechanism UDU includes, initially, positioning each of the elevation pins PN such that each of the elevation pins PN comes in contact with each of the support members MT mounted in each of the pinholes PH of the susceptor 218 and raising the elevation-pin elevating mechanism UDU. Thus, as shown in FIG. 4, each of the elevation pins PN and each of the support members MT is integrally formed, and each of the support members MT is separated from each of the pinholes PH, so that each of the support members MT and the wafer 200 move upward. As a result, the wafer 200 is separated and discharged from the susceptor 218.

Here, when the wafer 200 is separated from the susceptor 218, to reduce damage to the wafer 200, each of the support members MT is formed in a flange shape as shown in FIGS. 3 and 4 to increase a contact area of the wafer 200. Also, when the wafer 200 is held by the susceptor 218 (refer to FIG. 3), each of the support members MT is mounted in each of the pinholes PH with no gap therebetween to suppress dissipation of heat from each of the pinholes PH.

The substrate processing apparatus 101 may include a susceptor moving mechanism (not shown) in addition to the susceptor holding mechanism. The susceptor moving mechanism charges and discharges a plurality of susceptors 218 holding the wafers 200 between the susceptor holding mechanism and a boat 217 (or substrate holder) to stack the plurality of susceptors 218 in the boat 217.

As shown in FIGS. 5 through 7, the boat 217 is configured to stack and hold a plurality of susceptors 218 holding a plurality of wafers 200 (e.g., 50 to 100 wafers 200) in a horizontal direction in a state where the plurality of susceptors 218 are concentrically aligned in a lengthwise direction (or vertical direction) in multiple stages. That is, the plurality of wafers 200 are stacked in the boat 217 via the susceptors 218.

The boat 217 functions as a holder configured to hold each of the susceptors 218, and include a disk-shaped bottom plate 217a, a disk-shaped ceiling plate 217b, and three pillars for connecting the bottom plate 217a and the ceiling plate 217b. Also, a plurality of holding units HU protrude from the side of each of the pillars PR near the susceptor 218 (or wafer 200) (or near the central axis of the boat 217), and the susceptor 218 is placed on each of the holding units HU. The plurality of holding units HU are installed at regular intervals along axial directions of the respective pillars PR. An interval between the holding units HU in the axial directions of the respective pillars PR is set to be longer than a thickness dimension of the susceptors 218 so that a gas can widely spread over an entire region of one lateral surface (or a top surface of FIG. 7) of each of the wafers 200. Also, each of the pillars PR, each of the holding units HU, the bottom plate 217a, and the ceiling plate 217b are formed of a quartz (SiO₂) material as a heat-resistant material. Also, although installation of the three pillars PR are exemplified, when the susceptors 218 are set from a lateral direction of the boat 217, four or more pillars PR may be installed.

As shown in FIG. 1, to supply clean air to the substrate processing apparatus 101 in a cleaned atmosphere, a clean(ing) unit 134a including a supply fan and a dustproof filter is installed behind the buffer shelf 107 and configured to circulate the clean air inside the housing 111. Also, to supply the clean air to the susceptor 218 holding the wafer 200, a clean unit (not shown) including a supply fan and a dust proof filter is installed on a side opposite to a side of the wafer transfer apparatus elevator 125b, that is, a left side facing the front of the housing 111. Also, after clean air emitted from the clean unit passes through the susceptor 218 holding the wafer 200, the clean air is sucked into an exhaust apparatus (not shown) and exhausted out of the housing 111.

A pressure-resistant housing 140, which has a level of airtight performance to maintain a subatmospheric pressure (hereinafter, referred to as a negative pressure), is installed behind the wafer transfer apparatus (or substrate transfer apparatus) 125a. Due to the pressure-resistant housing 140, a load-lock chamber (or transfer chamber) is formed as a load-lock standby chamber having such a capacity as to contain the boat 217.

A wafer loading/unloading hole (or substrate loading/unloading hole) 142 is installed in a front wall 140a of the pressure-resistant housing 140 and opened or closed by a gate valve (or a mechanism for opening or closing the substrate loading/unloading hole) 143. A gas supply pipe 144 for supplying an inert gas, such as nitrogen gas, to the load-lock chamber 141 and a gas exhaust pipe (not shown) for exhausting the load-lock chamber 141 in a negative pressure are respectively connected to a pair of sidewalls of the pressure-resistant housing 140.

A cylinder-shaped processing furnace (or reaction furnace) 202 is installed as a reaction container above the load-lock chamber 141. A lower end of the processing furnace 202 is opened or closed by a furnace port shutter (or a furnace port gate valve or furnace port opening/closing mechanism) 147.

As schematically shown in FIG. 1, a boat elevator (or support holder elevating mechanism) 115 for raising and lowering the boat 217 is installed in the load-lock chamber 141. A seal cap 219 serving as a lid member is horizontally installed at an arm (not shown) as a connecting tool connected to the boat elevator 115. The seal cap 219 may vertically support the boat 217 and cover and close the lower end of the processing furnace 202.

Each driver (i.e., an electrical component such as an actuator) constituting the substrate processing apparatus 101 is electrically connected to a controller 240 as shown in FIG. 1, and the controller 240 controls an operation of each driver constituting the substrate processing apparatus 101 based on a predetermined control logic.

<Operation of Substrate Processing Apparatus>

The substrate processing apparatus 101 is constructed as described above. Hereinafter, an operation of the substrate processing apparatus 101, particularly, an operation of loading and unloading a wafer 200 with respect to the processing furnace 202, will be described.

As shown in FIG. 1, before the cassette 110 is supplied to the cassette stage 114, the cassette loading/unloading hole 112 is opened by the front shutter 113. Afterwards, the cassette 110 is loaded into the housing 111 through the cassette loading/unloading hole 112 and placed on the cassette stage 114. In this case, the wafer 200 placed on the cassette stage 114 is positioned vertically, and placed so that the wafer entrance hole of the cassette 110 faces upward.

Next, the cassette 110 is picked up from the cassette stage 114 by the cassette conveyance apparatus 118 and rotated by an angle of 90° toward the rear of the housing 111 such that the wafer 200 in the cassette 110 is positioned horizontally and the wafer entrance hole of the cassette 110 faces the rear of the housing 111. Subsequently, the cassette 110 is automatically conveyed and accommodated at a designated position of the cassette shelf 105 or the buffer shelf 107 by the cassette conveyance apparatus 118. That is, after the cassette 110 is temporarily stocked on the buffer shelf 107, the cassette 110 is transferred to the cassette shelf 105 or directly conveyed to the cassette shelf 105 by the cassette conveyance apparatus 118.

Thereafter, the slide stage 106 horizontally moves the cassette shelf 105 and positions the cassette 110 as a subject to be transferred such that the cassette 110 faces the wafer transfer apparatus 125a. The wafer 200 is picked up from the cassette 110 through the wafer entrance hole by the tweezers 125c of the wafer transfer apparatus 125a. In this case, in the susceptor holding mechanism, the elevation-pin elevating mechanism UDU is elevated to raise each of the elevation pins PN (refer to FIG. 4). Subsequently, due to the drive of the wafer transfer apparatus 125a, the wafer 200 is placed on each of the support members MT, which are integrally formed with the elevation pins PN, respectively. Then, the elevation-pin elevating mechanism UDU descends so that the elevation pins PN on which the wafer 200 is placed can descend, and the wafer 200 is held by the susceptor 218 as shown in FIG. 3. Afterwards, the wafer transfer apparatus 125a returns to the cassette 110, and the next wafer 200 is charged in the susceptor holding mechanism.

Next, when the wafer loading/unloading hole 142 of the load-lock chamber 141 previously maintained in an atmospheric state is opened by an operation of the gate valve 143, the susceptor 218 (refer to FIG. 3) holding the wafer 200 is discharged from the susceptor holding mechanism by drive of the susceptor moving mechanism. Afterwards, the susceptor 218 detached from the susceptor holding mechanism by the drive of the susceptor moving mechanism is loaded into the load-lock chamber 141 through the wafer loading/unloading hole 142 and charged in the boat 217. Thereafter, the susceptor moving mechanism returns to the susceptor holding mechanism, and the next susceptor 218 holding the wafer 200 is picked up. Then, the susceptor moving mechanism sequentially charges the susceptor 218 holding the wafer 200 in the boat 217 by performing the corresponding operation once more. Thus, as shown in FIG. 7, each of the susceptors 218 holding the wafer 200 is held by each of the holding units HU of the boat 217 and placed in a horizontal state.

Next, when a predetermined number of susceptors 218 (or wafers 200) are charged in the boat 217, the wafer loading/unloading hole 142 is closed by the gate valve 143. Afterwards, the lower end of the processing furnace 202 is opened by the furnace port shutter 147. Then, the boat 217 charged with each of the susceptors 218 and the seal cap 219 ascend due to the drive of the boat elevator 115. While the boat 217 is being loaded into the processing furnace 202, the lower end of the processing furnace 202 is closed by the seal cap 219.

After the boat 217 is loaded, each of the wafers 200 is arbitrarily processed in the processing furnace 202. After each of the wafers 200 is processed, the seal cap 219 descends due to the drive of the boat elevator 115 to open the lower end of the processing furnace 202 and take out the boat 217 from the processing furnace 202. Afterwards, a basically opposite operation to the above-described operation is performed, thereby withdrawing the cassette 110 containing each of the processed wafers 200 from the housing 111.

<Construction of Processing Furnace>

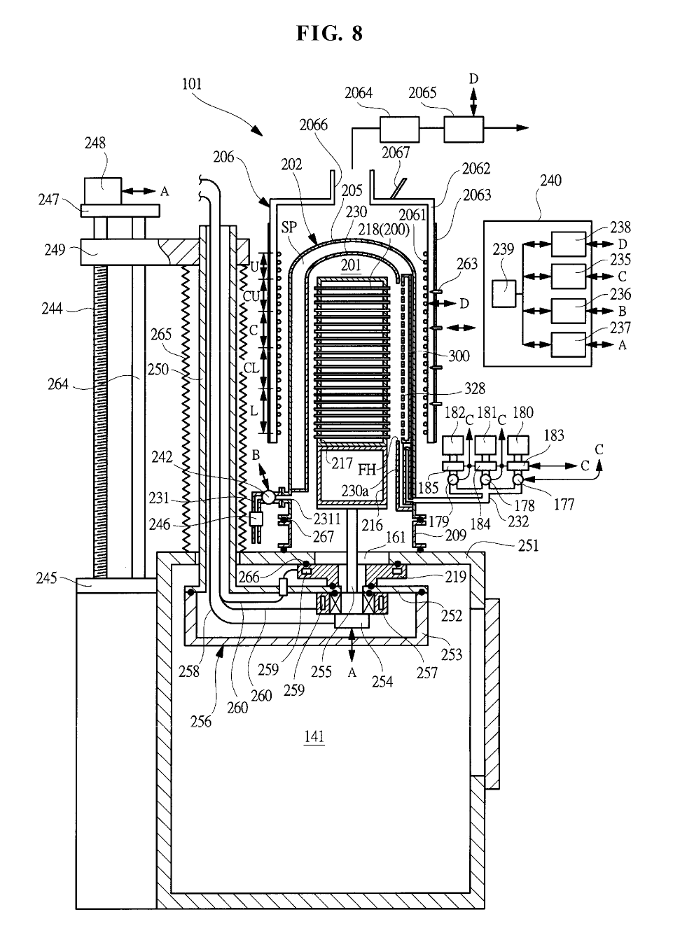

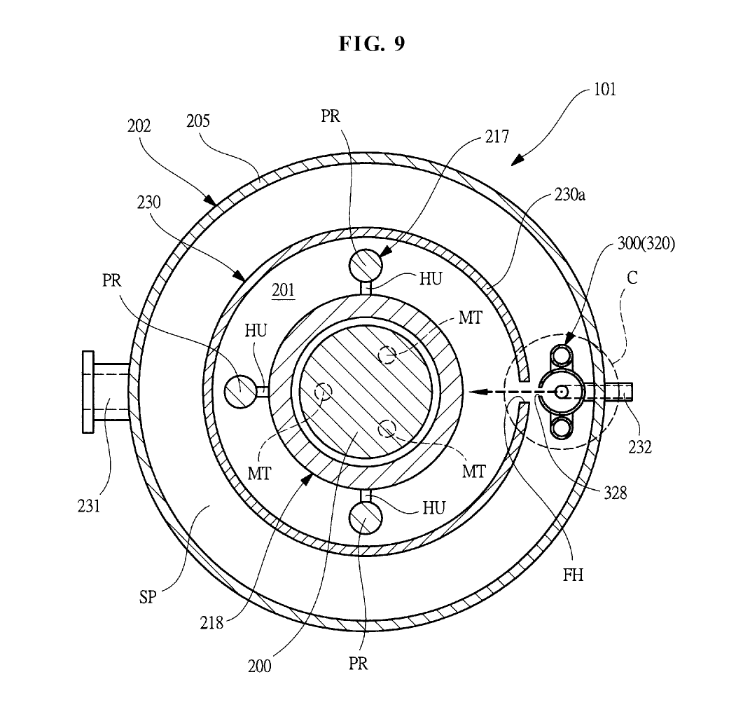

Hereinafter, the processing furnace 202 constituting the substrate processing apparatus 101 will be described with reference to the accompanying drawings. FIG. 8 is a schematic cross-sectional view of the processing furnace 202 of the substrate processing apparatus 101 and a periphery of the processing furnace according to a first embodiment of the present invention, and FIG. 9 is a longitudinal cross-sectional view illustrating a longitudinal section of the processing furnace of FIG. 8.

As shown in FIG. 8, an inductive heating apparatus 206 in a roughly cylindrical shape is installed around the processing furnace 202 to cover the processing furnace 202. The inductive heating apparatus 206 may apply a high-frequency (HF) current and heat each of the wafers 200 due to radiant heat. The inductive heating apparatus 206 includes an RF coil 2061 as an inductive heated body, a wall body 2062, and a cooling wall 2063. The RF coil 2061 is connected to an HF power source (not shown), and the HF current is supplied to the RF coil 2061 by the HF power source.

The wall body 2062 is formed in a cylindrical shape and is made of a metal, such as a stainless material, and an RF coil 2061 is installed on an inner wall of the wall body 2062. The RF coil 2061 is supported on a wall body 2062 by a coil support (not shown) supported on the inner wall of the wall body 2062, and the coil support is configured to form a predetermined gap (not shown) between the RF coil 2061 and the wall body 2062 in a radial direction of the wall body 2062.

The cooling wall 2063 is installed on an outer wall of the wall body 2062 to be concentric with the wall body 2062. A cooling medium channel (not shown) is formed in an entire region of the cooling wall 2063 to enable circulation of a cooling medium such as cooling water. A cooling medium supply unit (not shown) for supplying a cooling medium and a cooling medium discharge unit (not shown) for discharging a cooling medium are connected to the cooling wall 2063. By supplying the cooling medium from the cooling medium supply unit to the cooling medium channel and discharging the cooling medium from the cooling medium discharge unit, the cooling wall 2063 may be cooled off, and the wall body 2062 and an inside of the wall body 2062 are cooled off due to thermal conduction.

An opening 2066 is formed in the center of an upper end of the wall body 2062. A duct (not shown) is connected to a downstream side of the opening 2066, and a radiator 2064 serving as a cooling device and a blower 2065 serving as an exhaust device are connected to a downstream side of the duct.

An outer tube 205 functioning as a reaction pipe forming the processing furnace 202 to be concentric with the inductive heating apparatus 206 is installed inside the RF coil 2061. The outer tube 205 is formed of a SiO₂ material, which is a heat-resistant material, and has a cylindrical shape with its upper end closed and its lower end opened.

A manifold 209 forming the processing furnace 202 to be concentric with the outer tube 205 is installed in a lower portion of the outer tube 205. The manifold 209 is formed of, for example, a SiO₂ material or a stainless material and has a cylindrical shape with its upper and lower ends opened. The manifold 209 supports the outer tube 205 via an O-ring 267 serving as a seal member, and a gap between the manifold 209 and the outer tube 205 is held hermetically. The manifold 209 is supported by a holder (not shown) so that the outer tube 205 can be installed vertically. Also, the manifold 209 is not particularly limited to the case where the manifold 209 is installed independently of the outer tube 205. When the manifold 209 is formed integrally with the outer tube 205, the manifold 209 may not be installed in a separate manner.

As shown in FIG. 9, an inner tube 230 is installed inside the outer tube 205. The inner tube 230 is formed of a SiO₂ material, which is a heat-resistant material, and has a cylindrical shape with a bottom, similar to the outer tube 205. The inner tube 230 is installed to be concentric with the outer tube 205, and an annular gap SP is formed between the inner tube 230 and the outer tube 205. The processing chamber 201 is formed inside the inner tube 230, and the boat 217 is accommodated in the processing chamber 201.

The inner tube 230 includes a sidewall 230a, and an opening FH through which the processing chamber 201 disposed in the inner tube 230 communicates with the gap SP disposed outside the inner tube 230, is formed in the sidewall 230a. The opening FH is formed in a slit shape to extend in an axial direction of the inner tube 230 and serve as a gas circulation hole through which a gas used for a substrate processing process circulates through the gap SP into the processing chamber 201. Also, as shown in FIG. 8, a lower end of the inner tube 230 is closely bonded to an inner wall of the outer tube 205. The lower end of the inner tube 230 is bonded to the inner wall of the outer tube 205 above a gas exhaust hole 2311. Thus, a space between the gap SP and the processing chamber 201 is isolated (or hermetically sealed) from regions other than the opening FH.

The boat 217 is contained in the processing chamber 201 of the inner tube 230, and a central axis of the inner tube 230 coincides with a central axis of the boat 217. A plurality of susceptors 218 holding the wafers 200 are stacked in the boat 217, and the respective wafers 200 are vertically disposed in a horizontal posture to be aligned in a plurality of stages along a lengthwise direction of the inner tube 23.

A gas exhaust pipe 231 functioning as an exhaust unit communicating with the gas exhaust hole 2311 and a gas supply pipe 232 communicating with the gas supply nozzle 300 are connected to a side of the manifold 209 of the outer tube 205. The gas exhaust pipe 231 and the gas supply pipe 232 are installed opposite each other across the center of the wafer 200. Both the gas exhaust pipe 231 and the gas supply pipe 232 are formed of a SiO₂ material, which is a heat-resistant material, and connected by melting to an outer wall of the outer tube 205. Also, the gas exhaust pipe 231 and the gas exhaust hole 2311 may be installed, for example, at the manifold 209 instead of the outer tube 205. However, to prevent a high-temperature heated gas from being exposed to a rotation mechanism 254, the gas exhaust pipe 231 and the gas exhaust hole 2311 may be installed at the outer tube 205 far from the rotation mechanism 254, as in this embodiment. Also, a communication unit between the gas supply nozzle 300 and the gas supply pipe 232 may be installed, for example, at the manifold 209 instead of the outer tube 205.

The gas supply pipe 232 is branched into three pipes at an upstream side thereof, and the three branched pipes of the gas supply pipe 232 may be connected to a first gas source 180, a second gas source 181, and a third gas source 182 via valves 177, 178, and 179 and mass flow controllers (MFCs) 183, 184, and 185 serving as gas flow-rate controllers, respectively. A gas flow-rate controller 235 of the controller 240 is electrically connected to each of the MFCs 183, 184, and 185 and each of the valves 177, 178, and 179, and a flow rate of the supplied gas is controlled by the gas flow-rate controller 235 to a desired value at a desired time point. Also, the gas supply pipe 232 is further branched at the upstream side thereof and a further branched pipe of the gas supply pipe 232 is connected to an inert gas source (not shown) via a valve (not shown) and an MFC (not shown) serving as an inert gas flow-rate controller.

A vacuum exhaust apparatus 246, such as a vacuum pump, is connected to a downstream side of the gas exhaust pipe 231 via a pressure sensor (not shown) functioning as a pressure detector and an automatic pressure control (APC) valve 242 functioning as a pressure adjustor. The pressure controller 236 of the controller 240 is electrically connected to the pressure sensor and the APC valve 242. The pressure controller 236 controls a degree of opening of the APC valve 242, based on the pressure detected by the pressure sensor, so that an inner pressure of the processing chamber 201 reaches a desired pressure at a desired time point.

A seal cap 219 is installed as a furnace port cover for hermetically closing a lower opening of the manifold 209 below the manifold 209. The seal cap 219 is roughly formed in a disk shape using a metal material, for example, a stainless material. An O-ring 266 is installed as a seal member between the seal cap 219 and the ceiling plate 251. A rotation shaft 255 of the rotation mechanism 254 penetrates the seal cap 219, and an axial end (an upper side of the drawings) of the rotation shaft 255 is connected to an adiabatic case 216 rotatably installed and integrally formed with the boat 217. Thus, by rotating the rotation mechanism 254, the boat 217 may be rotated via the rotation shaft 255 and the adiabatic case 216 and furthermore, each of the wafers 200 may be rotated within the processing chamber 201.

The seal cap 219 is configured to ascend and descend in a vertical direction using an elevation motor 248 serving as an elevating mechanism installed outside the processing furnace 202. Thus, the boat 217 may be loaded and unloaded with respect to the processing chamber 201.

The adiabatic case 216, which is formed in a roughly cylindrical shape using, for example, a SiO₂ material, which is a heat-resistant material, is disposed under the boat 217. The adiabatic case 216 is configured to preclude heat generated by the inductive heating apparatus 206 from being transmitted to the side of the rotation mechanism 254. However, rather than being installed separately from the boat 217, the adiabatic case 216 may be integrally formed with the boat 217 under the boat 217. Instead of the adiabatic case 216, a plurality of adiabatic plates may also be installed under the boat 217, or may be installed under the adiabatic case 216 in addition to the adiabatic case 216.

Here, the boat 217 is preferably formed of a material from which contaminants are not emitted at a high degree of purity to inhibit mixture of a film with impurities during the formation of a film on the wafer 200. Also, to inhibit thermal degradation of the adiabatic case 216, the boat 217 is preferably formed of a material having a low thermal conductivity. In addition, to minimize a thermal effect on the wafer 200, the boat 217 is preferably formed of a material that is not inductively heated by an inductive heating apparatus 206. To satisfy the above-described conditions, in this embodiment, the boat 217 is formed of a SiO₂ material.

A drive controller 237 of the controller 240 is electrically connected to a rotation mechanism 254 and the elevation motor 248, and the drive controller 237 controls the rotation mechanism 254 and the elevation motor 248 at a desired time point to perform desired operations.

The inductive heating apparatus 206 is divided into a plurality of upper and lower zones, and an RF coil 2061 having a spiral shape is installed in the plurality of upper and lower zones. For example, as shown in FIG. 8, the lower zone is divided into five zones, and an RF coil L, an RF coil CL, an RF coil C, an RF coil CU, and an RF coil U are installed in the five zones, respectively. The RF coil L, the RF coil CL, the RF coil C, the RF coil CU, and the RF coil U installed respectively in the five zones are independently controlled.

Radiation thermometers 263 functioning as thermometer detectors for detecting an inner temperature of the processing chamber 201 are installed, for example, at four spots near the RF coil 2061 forming the inductive heating apparatus 206. Although at least one radiation thermometer 263 may be installed, temperature controllability may be improved by installing a plurality of radiation thermometers 263.

A temperature controller 238 of the controller 240 is electrically connected to the inductive heating apparatus 206 and each of the radiation thermometers 263, and the temperature controller 238 may control a conduction state to the inductive heating apparatus 206 based on information regarding temperature detected by each of the radiation thermometers 263. Also, the inner temperature of the processing chamber 201 is controlled by the temperature controller 238 so that the inner temperature reaches a desired temperature distribution at a desired time point.

The temperature controller 238 of the controller 240 is electrically connected to a blower 2065. The temperature controller 238 controls an operation of the blower 2065 according to a preset control logic. Specifically, the blower 2065 is operated to discharge an atmosphere present in a gap between the wall body 2062 and the outer tube 205 through the opening 2066. After the atmosphere is discharged through the opening 2066, the atmosphere is cooled off through a radiator 2064 and discharged from a downstream side of the blower 2065 to equipment. That is, the blower 2065 operates based on the control of the temperature controller 238, thereby cooling the inductive heating apparatus 206 and the outer tube 205.

The cooling medium supply unit and the cooling medium exhaust unit connected to the cooling wall 2063 are controlled by the controller 240 at a desired time point so that the cooling medium supply unit and the cooling medium exhaust unit reach a desired cooling state through the flow of the cooling medium to the cooling wall 2063. Also, to further promote the cooling of the outer tube 205 by improving the radiation of heat out of the processing furnace 202, the cooling wall 2063 may be installed. However, when a desired cooling state is obtained due to an operation of the blower 2065, the cooling wall 2063 may be not installed.

In addition to the opening 2066, an emergency pressure opening hole (not shown) and a pressure opening hole opening/closing apparatus 2067 for opening and closing the pressure open hole are installed at an upper end of the wall body 2062. For example, when an inside of the wall body 2062 is under an excessively high pressure due to a mixture of hydrogen gas and oxygen gas in the wall body 2062, that is, in an emergency, the high pressure acts on the wall body 2062. Also, relatively weak portions, for example, bolts, screws, or panels forming the wall body 2062, may be deformed or broken. Thus, to minimize damage to the substrate processing apparatus 101 due to the high pressure applied to the wall body 2062, the pressure opening hole opening/closing apparatus 2067 opens the pressure opening hole when the inside of the wall body 2062 reaches a predetermined pressure or higher, and releases an internal pressure of the wall body 2062.

<Construction of Periphery of Processing Furnace>

Next, construction of the periphery of the processing furnace 202 will be described with reference to FIG. 8. A lower substrate 245 is installed on an outer surface of the load-lock chamber 141 as a preliminary chamber. A guide shaft 264, which is in contact with the elevation stage 249 to direct the elevation stage 249 to move, and the ball screw 244, which is spirally combined with the elevation stage 249, are installed on the lower substrate 245. An upper substrate 247 is installed on upper ends of a guide shaft 264 set on the lower substrate 245 and the ball screw 244. The ball screw 244 is rotated by the elevation motor 248 installed on the upper substrate 247, thereby raising or lowering the elevation stage 249 due to the rotation of the ball screw 244.

A hollow elevation shaft 250 is installed in the elevation stage 249 in a vertical direction, and a connection between the elevation stage 249 and the elevation shaft 250 is hermetically formed. The elevation shaft 250 is raised and lowered with the elevation stage. The elevation shaft 250 penetrates the ceiling plate 251 forming the load-lock chamber 141. A through hole of the ceiling plate 251 through which the elevation shaft 250 is installed has a sufficient size as to prevent the ceiling plate 251 from contacting the elevation shaft 250. A bellows 265 is installed between the ceiling plate 251 forming the load-lock chamber 141 and the elevation stage 249 to cover a periphery of the elevation shaft 250. The bellows 265 is formed of a hollow elastic material having elasticity (e.g., an elastic body, such as heat-resistant rubber) and hermetically holds the load-lock chamber 141. The bellows 265 has a sufficient amount of elasticity to correspond to an amount of elevation of the elevation stage 249, and an inner diameter of the bellows 265 is sufficiently greater than an outer diameter of the elevation shaft 250. Thus, due to the elasticity of the bellows 265, the bellows 265 is not in contact with the elevation shaft 250.

An elevation substrate 252 is horizontally fixed at a lower end of the elevation shaft 250. A driver cover 253 is hermetically installed on a bottom surface of the elevation substrate 252 via a seal member, such as an O-ring. The elevation substrate 252 and the driver cover 253 constitute a driver receiving case 256 so that the inside of the driver receiving case 256 can be isolated from an inner atmosphere of the load-lock chamber 141.

A rotation mechanism 254 for rotating the boat 217 in the processing furnace 202 is installed in the driver receiving case 256, and a peripheral portion of the rotation mechanism 254 is cooled off by a cooling mechanism 257. Also, a power supply cable 258 is guided from an upper end of the elevation shaft 250 through a hollow portion of the elevation shaft 250 and connected to the rotation mechanism 254. Also, a cooling channel 259 is formed in each of the cooling mechanism 257 and the seal cap 219, and a cooling water conduit 260 for supplying cooling water (not shown) is connected to each of the cooling channels 259. The cooling water conduit 260 passes from the upper end of the elevation shaft 250 through the hollow portion of the elevation shaft 250.

The elevation motor 248 is rotated by the controller 240 to rotate a ball screw 244 so that the driver receiving case 256 can ascend and descend via the elevation stage 249 and the elevation shaft 250. By elevating the driver receiving case 256, the seal cap 219 hermetically installed on the elevation substrate 252 closes a furnace port 161 serving as an opening of the processing furnace 202 so that each of the wafers 200 can be in a film-forming state. Also, by lowering the driver receiving case 256, the boat 217 is lowered along with the seal cap 219 so that each of the wafers 200 can enter an external unloading state.

The gas flow-rate controller 235, the pressure controller 236, the drive controller 237, and the temperature controller 238 constitute a manipulation unit or an input/output (I/O) unit and are electrically connected to the main controller 239 for controlling the entire substrate processing apparatus 101. The gas flow-rate controller 235, the pressure controller 236, the drive controller 237, the temperature controller 238, and the main controller 239 constitute the controller 240. Thus, the processing furnace 202 of the substrate processing apparatus 101 and a peripheral structure thereof are constructed.

<Construction of Gas Supply Nozzle>

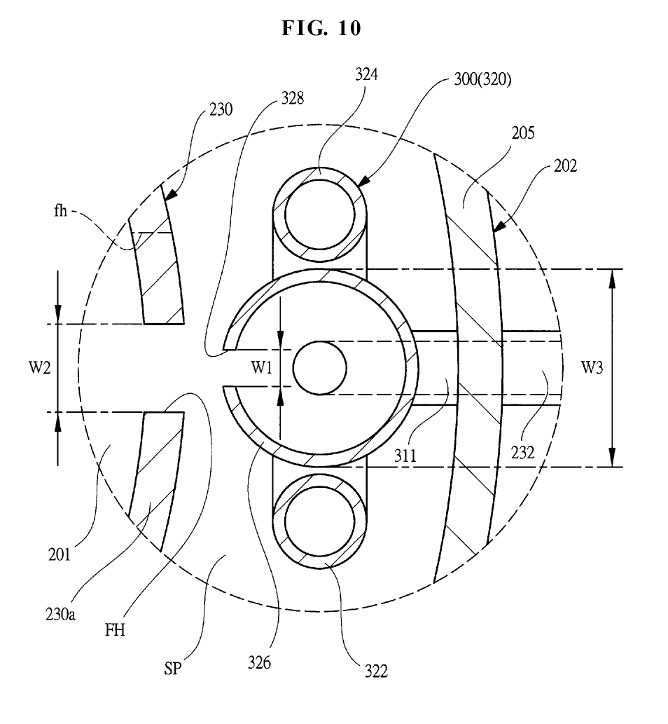

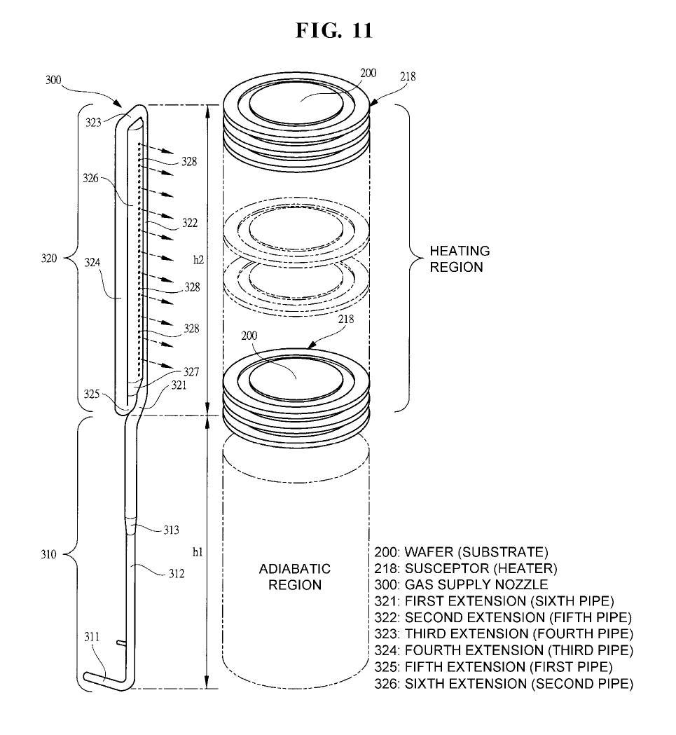

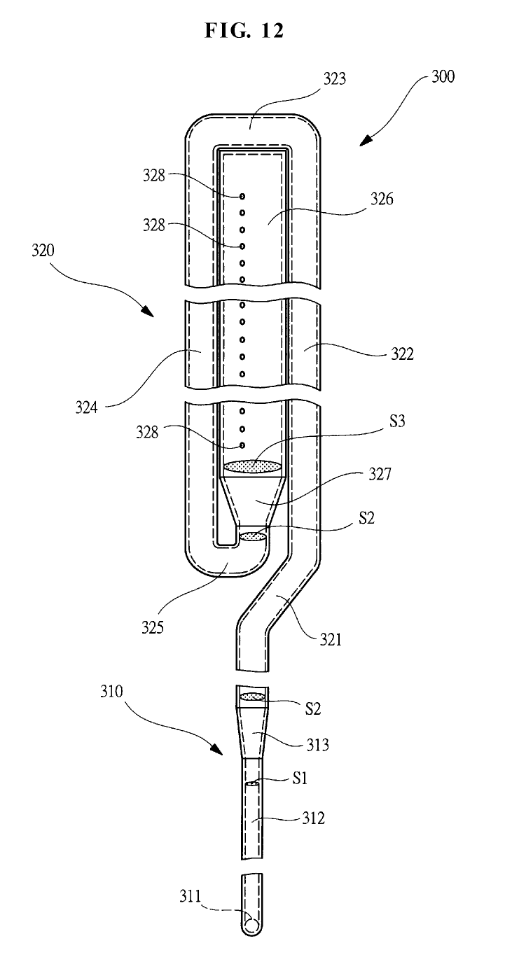

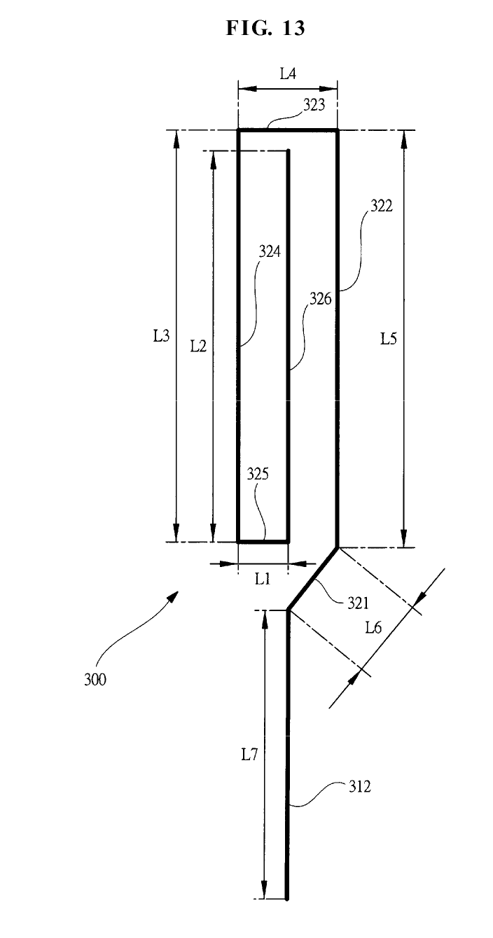

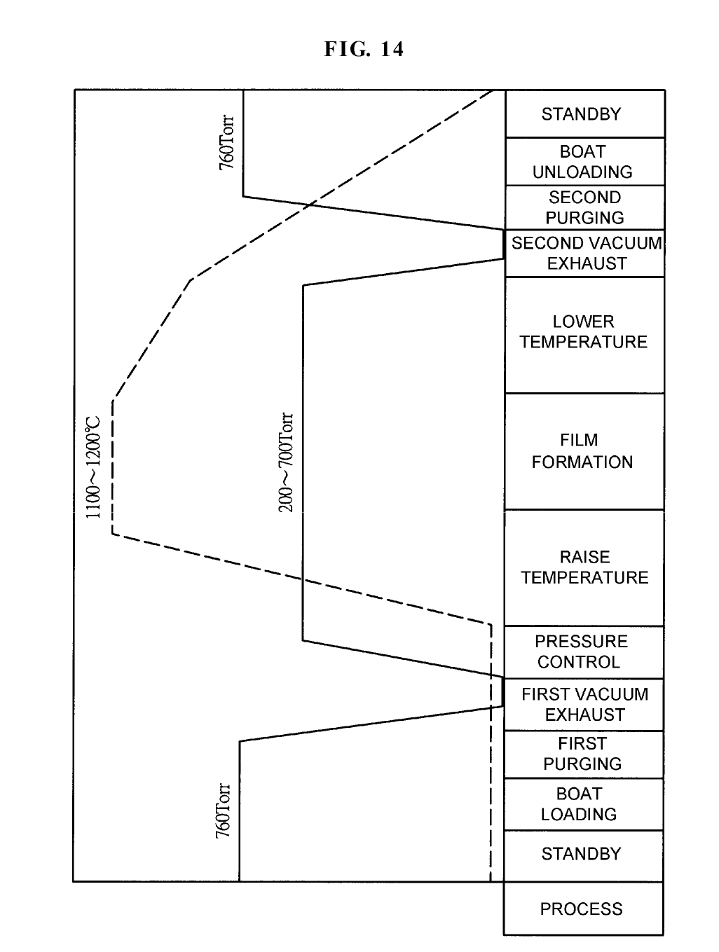

Hereinafter, the gas supply nozzle 300 constituting the substrate processing apparatus 101 will be described with reference to the accompanying drawings. FIG. 10 is an enlarged cross-sectional view of a dotted circle C of FIG. 9. FIG. 11 is a perspective view showing a positional relationship between a gas supply nozzle and a wafer according to a first embodiment. FIG. 12 is a lateral view of a detailed construction of the gas supply nozzle of FIG. 11. FIG. 13 is a diagram for explaining a pipe length of each portion of the gas supply nozzle of FIG. 12.

As shown in FIGS. 8 through 10, the gas supply nozzle (or gas nozzle) 300 is installed in a gap SP between the outer tube 205 and the inner tube 230 within the processing furnace 202 and extends in an axial direction of the processing furnace 202 to be out of contact with the outer tube 205 and the inner tube 230. A front end of the gas supply nozzle 300 faces a closing side of the outer tube 205, and a base end side of the gas supply nozzle 300 faces the opening of the outer tube 205. Also, the base end of the gas supply nozzle 300 is connected to a gas supply pipe 232 connected to the outer wall of the outer tube 205. Thus, the gas supply pipe 232 communicates with the gas supply nozzle 300 so that a gas supplied to the gas supply pipe 232 can be supplied to the gas supply nozzle 300. Here, the gas supply nozzle 300 supplies a gas to the inner tube 230 through the opening FH of the inner tube 230 toward a lateral direction of each of the wafers 200 in the processing chamber 201. The gas supply nozzle 300 is formed using a SiO₂ material, which is a heat-resistant material, in a hollow cylindrical shape.

As shown in FIG. 11, the gas supply nozzle 300 includes an L-shaped pipe unit 310 forming a base end of the gas supply nozzle 300, and a coiled pipe unit 320 forming a front end thereof. The L-shaped pipe unit 310 is disposed in a portion of the processing furnace 202, which is disposed opposite the adiabatic case 216 (refer to FIG. 8) installed under the boat 217 and a radial direction of the adiabatic case 216, that is, an adiabatic region having a height h1 that is not easily heated by each of the susceptors 218 of the processing furnace 202. In other words, the L-shaped pipe unit 310 extends from the lower end of the processing furnace 202 to a lower portion of a substrate holding region of the boat 217.

Meanwhile, the coiled pipe unit 320 is disposed in a portion of the processing furnace 202, which is disposed opposite the boat 217 and a radial direction thereof, that is, a heating region having a height h2 that may be uniformly heated by each of the susceptors 218 of the processing furnace 202. In other words, the coiled pipe unit 320 extends from the lower end of the boat 217 to the upper end thereof.

The L-shaped pipe unit 310 includes a connector 311, which extends in a radial direction of the processing furnace 202 and has one end connected to the gas supply pipe 232, and a base end (or a seventh pipe) 312, which has a lower end connected to the other end of the connector 311 and extends in an axial direction of the processing furnace 202, that is, in a stacking direction of the wafers 200 are stacked. A pipe length (or length dimension) of the base end 312 is set to be a pipe length L7 as shown in FIG. 13 and approximately equal to a height h1 of an adiabatic region (refer to FIG. 11) of the processing furnace 202.

As shown in FIGS. 11 and 12, a first channel area adjusting unit 313 for increasing the channel area of a pipe is installed in an approximately central portion in the lengthwise direction of the base end 312 from a lower end of the base end 312 to an upper end thereof. As can be seen from a crossed line part of FIG. 12, the first channel area adjusting unit 313 increases the channel area of the base end 312 from S1 to S2 (S1<S2). Thus, the flow velocity of a gas flowing toward the coiled pipe unit 320 may be reduced, thereby improving the heating efficiency of a gas (or facilitating the heating of the gas) in the coiled pipe unit 320. Here, since the first channel area adjusting unit 313 has a stepped portion to have a tapered sectional shape, when the gas supply nozzle 300 is fixed to the processing furnace 202 using the first channel area adjusting unit 313, the first channel area adjusting unit 313 may function as a positioner. In the above-described configuration, positional precision of the gas supply nozzle 300 installed in the processing furnace 202 may be improved.

As shown in FIGS. 12 and 13, the coiled pipe unit 320 includes a first extension part (or a sixth pipe) 321, a second extension part (or a fifth pipe) 322, a third extension part (or a fourth pipe) 323, a fourth extension part (or a third pipe) 324, a fifth extension part (or a first pipe) 325, and a sixth extension part (or a second pipe) 326 from the base end 312 of an L-shaped pipe unit 310.

The first extension part 321 extends toward an upper portion of the drawing from the right of the base end 312 (in an inclined direction), that is, in circumferential and axial directions of the wafer 200. The other end (i.e., a second end, a lower end of the drawings) of the first extension part 321 is connected to an upper end of the base end 312, and a pipe length of the first extension part 321 is set to be L6 (L6<L7). Also, rather than extending in the inclined direction, the first extension part 321 may extend in the circumferential direction of the wafer 200 perpendicular to the base end 312. In this case, a pipe length L5 of the second extension part 322 may be slightly increased to prevent interference between the first and fifth extension parts 321 and 325.

The second extension part 322 extends toward the upper portion of the drawing from the first extension part 321, that is, in the stacking direction of the wafers 200, which is parallel to the base end 312. The other end (or a second end, a lower end of the drawings) of the second extension part 322 is connected to one end (or a first end, an upper end of the drawings) of the first extension part 321, and the pipe length of the second extension part 322 is set to be L5 (L5>L6).

The third extension part 323 extends toward a left portion of the drawing from the second extension part 322, that is, in the circumferential direction of the wafer 200 perpendicular to the base end 312. The other end (or a second end, a right end of the drawings) of the third extension part 323 is connected to one end (or a first end, an upper end of the drawings) of the second extension part 322, and the pipe length of the third extension part 323 is set to be L4 (L4<L5).

The fourth extension part 324 extends toward a lower portion of the drawing from the third extension part 323, that is, in the stacking direction of the wafers 200, which is parallel to the base end 312. The other end (or a second end, an upper end of the drawings) of the fourth extension part 324 is connected to one end (or a first end, a left end of the drawings) of the third extension part 323, and the pipe length of the fourth extension part 324 is set to be L3 (L3>L4). Also, a pipe length L3 of the fourth extension part 324 is set to be slightly shorter than the pipe length L5 of the second extension part 322 (L3<L5), and the fourth and second extension parts 324 and 322 have such a positional relationship as to roughly overlap each other in the circumferential direction of the wafer 200.

The fifth extension part 325 extends toward a right portion of the drawing from the fourth extension part 324, that is, along the circumferential direction of the wafer 200 perpendicular to the base end 312. The other end (or a second end, a left end of the drawings) of the fifth extension part 325 is connected to one end (or a first end, a lower end of the drawings) of the fourth extension part 324, and the pipe length of the fifth extension part 325 is set to be L1 (L1<L3). Also, the pipe length L1 of the fifth extension part 325 is set to be shorter than the pipe length L4 of the third extension part 323 (L1<L4), and at least portions of the fifth and third extension parts 325 and 323 have such a positional relationship as to overlap each other in the stacking direction of the wafers 200. Thus, the fifth extension part 325 is disposed at the lower end of the boat 217, while the third extension part 323 is disposed at the upper end thereof. Accordingly, the fifth and third extension parts 325 and 323 are installed at one end and the other end of the stacking direction of the wafers 200, respectively.

The sixth extension part 326 extends toward an upper portion of the drawing from the fifth extension part 325, that is, in the stacking direction of the wafers 200, which is parallel to the base end 312. One end (or a first end, a lower end of the drawings) of the sixth extension part 326 is connected to one end (or a first end, a right end of the drawings) of the fifth extension part 325, and the other end (or a second end, an upper end of the drawings) of the sixth extension part 326 is disposed in the third extension part 323. A pipe length of the sixth extension part 326 is set to be L2 (L2>L1). The pipe length L2 of the sixth extension part 326 is shorter than the pipe length L3 of the fourth extension part 324 (L2<L3). At least portions of the sixth and fourth extension parts 326 and 324 have such a positional relationship as to overlap each other in the circumferential direction of the wafer 200.

Here, the sixth extension part 326 is installed on the same pipe axis as the base end 312. Thus, when the connector 311 is connected to the gas supply pipe 232, the gas supply nozzle 300 is stably supported by the base end 312. That is, rather than being inclined, the gas supply nozzle 300 may be supported to be straight. Furthermore, positional deviation of the gas supply nozzle 300 due to oscillation or instability of a gas supply position may be suppressed.

As shown in FIG. 12, a second channel area adjusting unit 327 for slowly increasing the channel area of a pipe is installed at one end (or a lower end of FIG. 12) of the sixth extension part 326 from a lower end of the sixth extension part 326 toward an upper end thereof. As can be seen from the crossed line part of FIG. 12, the second channel area adjusting unit 327 increases the channel area of the sixth extension part 326 from S2 to S3 (S1<S2<S3). Thus, a gas pressure in the sixth extension part 326 may be easily uniformized, thus uniformizing a flow velocity of a gas supplied (emitted) from a plurality of gas supply holes 328 installed in the sixth extension part 326 toward the wafer 200. That is, the gas may be uniformly supplied to each of the wafers 200 held in each of the susceptors 218 and furthermore, uniformity in film thickness of the wafer 200 may be enhanced. In addition, the first extension part 321, the second extension part 322, the third extension part 323, the fourth extension part 324, and the fifth extension part 325 are set to have substantially the same channel area S2.

The other end (or an upper end) of the sixth extension part 326 is closed, and a plurality of gas supply holes 328 are formed parallel to an axial direction of the sixth extension part 326 at a portion where the channel area of the sixth extension part 326 is set to be S3. Each of the gas supply holes 328 is formed in a circular shape and supplies a gas from the outside of the processing furnace 202 to each of the wafers 200 stacked on the boat 217 in a horizontal direction. As shown in FIG. 10, a diameter W1 of each of the gas supply holes 328 is set to be smaller than a wide dimension (i.e., width) W2 of the opening FH installed in the sidewall 230a of the inner tube 230, which is measured in the circumferential direction of the inner tube 230 of the opening FH (W1<W2). Thus, each of the gas supply holes 328 may be reliably disposed opposite the opening FH so that a gas supplied through each of the gas supply holes 328 can be reliably supplied to each of the wafers 200 as denoted by dotted arrows of FIGS. 9 and 11.

Each of the gas supply holes 328 is opened toward the center of each of the wafers 200 and faces a space between the susceptors 218 (or between the wafers 200). Thus, a gas may be supplied to the surface of each of the wafers 200 without stains. Here, a plurality of gas supply nozzles 300 are preferably installed at predetermined intervals along a circumferential direction of the gap SP to enable uniform supply of a gas to the entire surface of each of the wafers 200. For example, when two gas supply nozzles 300 are installed, the gas supply nozzles 300 are disposed opposite each other across the center of the wafer 200 in a radial direction of the wafer 200 so that a gas can be uniformly supplied to the entire surface of the wafer 200. However, in this case, the inner tube 230 needs to be divided into two disposed opposite each other in a radial direction thereof in order to install another opening FH in the inner tube 230 such that the openings FH are disposed opposite each other in the radial direction of the inner tube 230.

Moreover, the width W2 of the opening FH is set to be smaller than an outer diameter W3 of the sixth extension part 326. That is, due to a size relationship in which (the diameter W1 of the gas supply hole 328<the width W2 of the opening FH<the outer diameter W3 of the sixth extension part 326), a gas supplied to the inner tube 230 does not easily leak from the inner tube 230. Thus, wasteful consumption of a gas is inhibited.

However, the width W2 of the opening FH may be optionally determined. For example, to facilitate the heating of the gas supply nozzle 300, the sidewall 230a of the inner tube 230 may have, for example, a width dimension equal to the width of an opening covering at least a portion of the fourth extension part 324 toward the radial direction of the inner tube 230 (refer to a dotted line fh of FIG. 10). Thus, the width dimension of the opening may be increased, and a larger portion of the gas supply nozzle 300 may be directly disposed opposite each of the susceptors 218 rather than disposed via the inner tube 230, and the heating efficiency of a gas circulating inside the gas supply nozzle 300 may be improved.

<Process of Processing Substrate>

Hereinafter, a process of processing a substrate in a method of fabricating a substrate using the substrate processing apparatus 101 will be described with reference to FIGS. 8 and 14. In this embodiment, a method of forming a semiconductor film, such as a silicon (Si) film, using an epitaxial growth process, on a substrate, such as a wafer, as a substrate processing process (a method of fabricating a semiconductor device) will be described. Also, although a method of fabricating a semiconductor device will be described as an example in this embodiment, a method of forming a substrate according to this embodiment is not limited to the method of fabricating the semiconductor device. For example, a semiconductor film, such as a Si film, is formed on a wafer, which is a semiconductor substrate of a first conductivity type (e.g., a p type) using an epitaxial growth process of a second conductivity type (e.g., an n type) opposite to the first conductivity type, and the formation of the semiconductor film may be applied to a method of fabricating a solar cell including forming a pn junction.

FIG. 14 is a timing chart showing a processing sequence of a substrate processing apparatus. In FIG. 14, a dashed line denotes a temperature (° C.) in the processing chamber 201, and a solid line of FIG. 14 denotes a pressure (Torr) in the processing chamber 201. In addition, in the following description, an operation of each component constituting the substrate processing apparatus 101 is controlled by the controller 240.

To begin with, the processing chamber 201 is in a standby state prior to the loading of the boat 217 into the processing chamber 201 shown in FIG. 8 (a standby process of FIG. 14). The standby state denotes a state where the boat 217 is disposed in the load-lock chamber 141 disposed underneath the processing chamber 201, and each of the susceptors 218 holding the wafer 200 is charged in the boat 217.

When each of the susceptors 218 holding the wafer 200 is charged in the boat 217, the standby process may be followed by elevating the elevation stage 249 and the elevation shaft 250 due to upward rotation [or forward drive] of the elevation motor 248. Thus, as shown in FIG. 8, the boat 217 is elevated, loaded into the processing chamber 201, and conveyed (boat-loaded) into the inner tube 230 (a boating loading process of FIG. 14). Afterwards, the seal cap 219 seals the ceiling plate 251 via the O-ring 266. In this case, the internal pressure of the processing chamber 201 reaches, for example, 760 Torr (=760×133.3 Pa). Here, the boat loading process constitutes a “process of conveying the substrate into the reaction container” of the present invention.

The boat loading process is followed by supplying an inert gas, for example, N₂ gas, to the processing chamber 201, thereby replacing the processing chamber 201 in the processing furnace 202 with the inert gas (a first purging process of FIG. 14). Also, the inert gas is supplied from an inert gas source (not shown), which is connected to the gas supply pipe 232, via each of the gas supply holes 328 of the gas supply nozzle 300.

The first purging process is followed by filling the processing chamber 201 with an inert gas, exhausting the processing chamber 201 using the vacuum exhaust apparatus 246 to reach a desired pressure, and reducing an internal pressure of the processing chamber 201 (a first vacuum exhaust process of FIG. 14).

The first vacuum exhaust process is followed by measuring the internal pressure of the processing chamber 201 using a pressure sensor and feedback-controlling the APC valve (or pressure controller) 242 based on the measured pressure (a pressure control process of FIG. 14). In this case, an inert gas, for example, N₂ gas, is supplied from an inert gas source (not shown) connected to the gas supply pipe 232 via each of the gas supply holes 328 of the gas supply nozzle 300. Due to the pressure control process, an internal pressure of the processing chamber 201 is adjusted to a predetermined processing pressure selected within the range of 16,000 Pa to 93,310 Pa. For example, the internal pressure of the processing chamber 201 ranges from 200 Torr to 700 Torr (or 200×133.3 Pa to 700×133.3 Pa). Also, after the pressure control process, controlling the internal pressure of the processing chamber 201 is performed to maintain a constant processing pressure until a second vacuum exhaust process is reached as shown in FIG. 4.

In addition, by operating the blower 2065, a gas or air is circulated between the inductive heating apparatus 206 and the outer tube 205, thereby cooling off the sidewall of the outer tube 205, the gas supply nozzle 300, each of the gas supply holes 328, and the gas exhaust hole 2311. Cooling water serving as a cooling medium flows through the radiator 2064 and the cooling wall 2063, and the inside of the inductive heating apparatus 206 is cooled off via the wall body 2062. Also, to control each of the wafers 200 to a desired temperature, an HF current is applied to the inductive heating apparatus 206 so that an inductive current (or an overcurrent) can occur in each of the susceptors 218.

Specifically, at least each of the susceptors 218 in the processing furnace 202 is inductively heated by the inductive heating apparatus 206, and each of the wafers 200 held by each of the susceptors 218 is heated due to radiant heat (a temperature raising process of FIG. 14). Specifically, when the HF current is supplied to the inductive heating apparatus 206, an HF electromagnetic field occurs in the processing furnace 202, and an overcurrent occurs in each of the susceptors 218, which is an subject to be induced, due to the HF electromagnetic field. Each of the susceptors 218 is inductively heated due to the overcurrent, and each of the wafers 200 is then heated due to radiant heat generated by each of the susceptors 218. Here, heat is transmitted from the peripheral portion 218a of the susceptor 218 to the central portion 218b thereof due to thermal conduction so that the entire susceptor 218 can be heated. Also, the temperature raising process constitutes a “process of processing a substrate” according to the present invention.

As described above, the substrate processing apparatus 101 adopts a cold wall technique by which each of the wafers 200 is heated by inductive heating. Here, even if each of the wafers 200 is directly inductively heated due to the HF electromagnetic field caused by supplying the HF current to the inductive heating apparatus 206, the amount of heating is deficient. Accordingly, in the substrate processing apparatus 101 using the cold wall technique, each of the wafers 200 is held in each of the susceptors 218, which is an subject to be induced, to increase efficiency of inductive heating of each of the wafers 200. That is, the susceptors 218 not only serve to hold the wafers 200 but also significantly function as heating sources inductively heated due to an HF electromagnetic field to heat the wafers 200.

When each of the susceptors 218 is inductively heated, the temperature controller 238 monitors temperature information detected by each of the radiation thermometers 263 such that the inside of the processing furnace 202 (or the processing chamber 201) has a desired temperature distribution, and feedback-controls a conduction state to the inductive heating apparatus 206 based on the temperature information. When the temperature of the inside of the processing furnace 202 is raised, the gas supply nozzle 300 is also heated with an increase in the temperature of the processing furnace 202. Accordingly, by heating a gas circulating inside the gas supply nozzle 300, the temperature of a gas supplied to each of the wafers 200 through each of the gas supply holes 328 may be raised to an optimum temperature for forming a film.

Here, the gas supply unit 300 includes the coiled pipe unit 320 by which a gas circulation path is increased. The first through sixth extension parts 321 to 326 forming the coiled pipe unit 320 are disposed approximately the same distance from each of the susceptors 218 serving as a heating source.

For this reason, without preparing a large-sized processing furnace as in the art, the gas supply nozzle 300 may be disposed in the gap SP between the outer tube 205 and the inner tube 230 to save a space. Also, since the first through sixth extension parts 321 to 325 forming the coiled pipe unit 320 are disposed approximately the same distance from the respective susceptors 218, almost the entire area of the coiled pipe unit 320 may be heated to the same temperature, thereby improving the heating efficiency of a gas in the gas supply nozzle 300. Also, by disposing the gas supply nozzle 300 in the gap SP to save a space, a distance between each of the gas supply holes 328 and each of the wafers 200 may be increased without preparing a large-sized processing furnace 202. As a result, before a gas reaches each of the wafers 200 through each of the gas supply holes 328, the gas may be heated more effectively by each of the susceptors 218.

Furthermore, the coiled pipe unit 320 of the gas supply nozzle 300 may be neither folded nor coiled at two portions of the third and fifth extension parts 323 and 325, unlike the above description. According to the shape of the processing furnace 202 (or the gap SP), the number of extension parts may be further increased so that the coiled pipe unit 320 may be, for example, folded and coiled at four portions. Also, the gas supply nozzle 300 is not limited to a SiO₂ material and may be formed of a material, for example, silicon carbide (SiC), which may be easily heated due to radiant heat of each of the susceptors 218. However, the gas supply nozzle 300 is preferably formed of a material that generates a smaller amount of inductive heat than carbon or carbon graphite.

Next, the blower 2065 is driven during the temperature raising process. Specifically, the blower 2065 is controlled to a preset control amount such that the outer wall of the outer tube 205 is cooled to a temperature of, for example, 600° C. or lower, which is much lower than a temperature at which a film is grown on each of the wafers 200. Each of the wafers is heated to a predetermined processing temperature selected from the range of 700 to 1200° C. For example, each of the wafers 200 is heated to a temperature of 1100 to 1200° C.

In addition, for example, when trichlorosilane (SiHCl₃) gas is used as a source gas and hydrogen (H₂) gas is used as a carrier gas, each of the susceptors 218 is inductively heated to a temperature of 1150° C. or higher. Also, although each of the wafers 200 is heated to a predetermined processing temperature selected from the range of 700 to 1200° C., even if an arbitrary processing temperature is selected, the blower 2065 is controlled to a preset control amount such that the outer wall of the outer tube 205 is cooled to a temperature of, for example, 600° C. or lower, which is much lower than a temperature at which a film is grown on each of the wafers 200.

The temperature raising process is followed by rotating the boat 217 by rotating the rotation mechanism 254 to rotate each of the wafers 200 in the processing furnace 202. Afterwards, when the temperature of each of the wafers 200 is stable, gases are respectively supplied from the first through third gas sources 180, 181, and 182. Also, degrees of opening of the MFCs 183, 184, and 185 are controlled and the valves 177, 178, and 179 are opened such that the gases are supplied from the gas sources 181, 182, and 183 at desired flow rates, respectively. Thus, the respective gases are mixed through the gas supply pipe 232 and supplied to the gas supply nozzle 300. Here, to inhibit formation of a film due to the gas circulated through the gas supply nozzle 300, the gas supply nozzle 300 is adjusted to a temperature of 1,000° C. or lower.

Although a flow rate of the gas supplied to the gas supply nozzle 300 depends on the number of wafers 200 on which a one-time film-forming process is performed, the flow rate is controlled to range from, for example, 26.25 to 262.5 slm. Also, the unit “slm” of the flow rate denotes the flow rate per one minute in a standard state (or under an atmospheric pressure of 101,325 Pa at 0° C.), which is calculated in terms of liters. Accordingly, when calculated with respect to a standard-state gas, a flow rate of 1 slm may be represented by 1.67×10⁻⁶ m³/sec. Hereinafter, the flow rate of a gas will be described using the unit “slm.”

Here, the first gas source 180, the second gas source 181, and the third gas source 182 are filled with dichlorosilane (SiH₂Cl₂), SiHCl₃, and silicon tetrachloride (SiCl₄) serving as Si-based and silicon-germanium (SiGe-based source gases, diborane (B₂H₆), BCl₃, and phosphine (PH₃) serving as doping gases, and hydrogen (H₂) gas serving as a carrier gas.

Since a flow-rate sectional area S3 (refer to FIG. 12) of the sixth extension part 326 forming the gas supply nozzle 300 is much larger than the opening area of each of the gas supply holes 328, an internal pressure of the sixth extension part 326 becomes higher than that of the processing chamber 201. Accordingly, gases jetted through the respective gas supply holes 328 are supplied at a roughly uniform flow rate/flow velocity to the inside of the processing chamber 201. For example, in this embodiment, each of the gas supply holes 328 has an opening diameter of φ1.5 mm, and the sixth extension part 326 has a channel diameter of φ35 mm. Thus, loss of the pressure of a gas flowing through the sixth extension part 326 may be suppressed, and the flow rates/flow velocities of the gases jetted through the respective gas supply holes 328 may be roughly uniformized.

The gas supplied into the processing chamber 201 passes between the respective wafers 200, widely spreads on the surface of each of the wafers 200, reaches the gas exhaust hole 2311, and is exhausted through the gas exhaust hole 2311 out of the gas exhaust pipe 231. In this case, when the gas passes between the respective wafers 200, the gas is heated by each of the susceptors 218 and comes into contact with each of the heated wafers 200. Thus, a semiconductor film, such as a Si film, is formed on the surface of each of the wafers 200 using an epitaxial growth process (a film-forming process of FIG. 14).

The film-forming process is followed by stopping the application of the HF current to the inductive heating apparatus 206 to lower the temperature of the processing chamber 201 after a predetermined time has elapsed (a temperature lowering process of FIG. 14). Also, by operating the vacuum exhaust apparatus 246 until the inside of the processing chamber 201 reaches a desired pressure, an atmosphere of the processing chamber 201 is vacuum-exhausted, while reducing the internal pressure of the processing chamber 201 (a second vacuum exhaust process of FIG. 14). Subsequently, an inert gas, for example, N₂ gas, is supplied from an inert gas source (not shown) to the inside of the processing chamber 201 to replace the inner atmosphere of the processing chamber 201 with the inert gas and return the internal pressure of the processing chamber 201 to an atmospheric pressure (a second purging process of FIG. 14).

The second purging process is followed by rotating (reversely driving) the rotation motor 248 downward to lower the seal cap 219. Thus, a lower end of the manifold 209 is opened, each of the processed wafers 200 is unloaded from the lower end of the manifold 209 out of the processing furnace 202 (i.e., toward the load-lock chamber 141) in a state where each of the processed wafers 200 is held in the boat 217 (a boat unloading process of FIG. 14). Then, each of the processed wafers 200 may be withdrawn from the boat 217 (wafer discharging). Afterwards, the substrate processing apparatus 101 returns to a standby state. In this way, the semiconductor film may be formed on the surface of each of the wafers 200.

<Representative Effects of First Embodiment>

According to the technical idea described in the first embodiment, at least one of a plurality of effects described below can be obtained.

(1) According to the first embodiment, the gas supply nozzle 300 includes the fifth and sixth extension parts 325 and 326 extending in a circumferential direction of at least the wafer 200, the first, third, and fifth extension parts 321, 323, and 325 extending in the circumferential direction of the wafer 200, and the first, second, fourth, and sixth extension parts 321, 322, 324, and 326 extending in the stacking direction of the wafers 200, thereby increasing a length of a gas circulation path. Accordingly, a gas flowing through the gas supply nozzle 300 may be sufficiently heated due to radiant heat of each of the susceptors 218, and occurrence of slip or haze on each of the wafers 200 may be suppressed.

(2) According to the first embodiment, since the first, third, and fifth extension parts 321, 323, and 325 forming the gas supply nozzles 300 extend in the circumferential direction of the wafer 200, the gas supply nozzle 300 may be disposed in the gap SP between the outer tube 205 and the inner tube 230 to save a space without preparing a conventional large-sized processing furnace. That is, a dead space of the processing furnace 202 may be effectively used so that performances of the substrate processing apparatus 101 can be improved without increasing the size thereof.

(3) According to the first embodiment, since a diameter dimension of the gas supply nozzle 300 in the radial direction of the wafer 200 may be reduced, a distance between each of the gas supply holes 328 and each of the wafers 200 may be increased without increasing the size of the processing furnace 202. Thus, before gas reaches each of the wafers 200 through each of the gas supply holes 328, the gas may be heated by each of the susceptors 218 more effectively, and the occurrence of slip or haze on each of the wafers 200 may be suppressed.

(4) According to the first embodiment, since the first through sixth extension parts 321 to 326 are disposed in a region where a plurality of susceptors 218 are stacked, that is, in a heating region that may be uniformly heated by the respective susceptors 218, a decrease in temperature of a gas heated in the gas supply nozzle 300 may be inhibited, and the heating efficiency of the gas in the gas supply nozzle 300 may be improved.

(5) According to the first embodiment, since the first through sixth extension parts 321 to 326 are disposed approximately the same distance from the respective susceptors 218, almost the entire region of the coiled pipe unit 320 including the first through sixth extension parts 321 to 326 may be heated to the same temperature. As a result, the heating efficiency of the gas in the gas supply nozzle 300 may be enhanced.

(6) According to the first embodiment, the first channel area adjusting unit 313 for gradually increasing the channel area of a pipe is installed in the approximately central portion in the lengthwise direction of the base end 312 from the lower end of the base end 312 to the upper end thereof. Thus, a flow velocity of the gas flowing toward the coiled pipe unit 320 may be reduced, thereby improving the heating efficiency of a gas in the coiled pipe unit 320, that is, facilitating the heating of the gas.

(7) According to the first embodiment, since the second channel adjusting unit 327 for gradually increasing the channel area of a pipe is installed at one end of the sixth extension part 326 from the lower end of the sixth extension part 326 toward the upper end thereof, it becomes easy to uniformize the pressure of a gas in the sixth extension part 326. Thus, flow velocities of gases supplied through the respective gas supply holes 328 installed in the sixth extension part 326 to the wafers 200 may be uniformized. As a result, gas can be uniformly supplied to each of the wafers 200 held in each of the susceptors 218, and uniformity in film thickness of the wafers 200 may be improved.

(8) According to the first embodiment, since the sixth extension part 326 is installed on the same pipe axis as the base end 312, the gas supply nozzle 300 can be stably supported by the base end 312. That is, rather than being inclined, the gas supply nozzle 300 may be supported to be straight. Also, positional deviation of the gas supply nozzle 300 due to oscillation or instability of a gas supply position may be suppressed.

(9) According to the first embodiment, the diameter W1 of each of the gas supply holes 328 is set to be smaller than the width W2 of the opening FH installed in the sidewall 230a of the inner tube 230 (W1<W2). Thus, each of the gas supply holes 328 may be reliably disposed opposite the opening FH. As a result, a gas supplied through each of the gas supply holes 328 can be reliably supplied to each of the wafers 200.

(10) According to the first embodiment, the width W2 of the opening FH is set to be smaller than the outer diameter W3 of the sixth extension part 326. That is, due to a size relationship in which (the diameter W1 of the gas supply hole 328<the width W2 of the opening FH<the outer diameter W3 of the sixth extension part 326), a gas supplied to the inner tube 230 does not easily leak out of the inner tube 230. Thus, wasteful consumption of a gas is inhibited.

(11) By applying the substrate processing apparatus 101 described in the first embodiment to a substrate processing process of a method of fabricating a substrate, a method of processing a substrate has at least one of the plurality of effects mentioned above.

(12) By applying the substrate processing apparatus 101 described in the first embodiment to a substrate processing process of a method of fabricating a semiconductor device, the method of fabricating the semiconductor device has at least one of the plurality of effects mentioned above.

(13) By applying the substrate processing apparatus 101 described in the first embodiment to a substrate processing process of a method of fabricating a solar cell, the method of fabricating the solar cell has at least one of the plurality of effects mentioned above.

### Second Embodiment

Hereinafter, a substrate processing apparatus according to a second embodiment of the present invention will be described in detail with reference to the drawings. The same reference numerals are used to denote components having the same functions as in the first embodiment, and a detailed description thereof will be omitted.

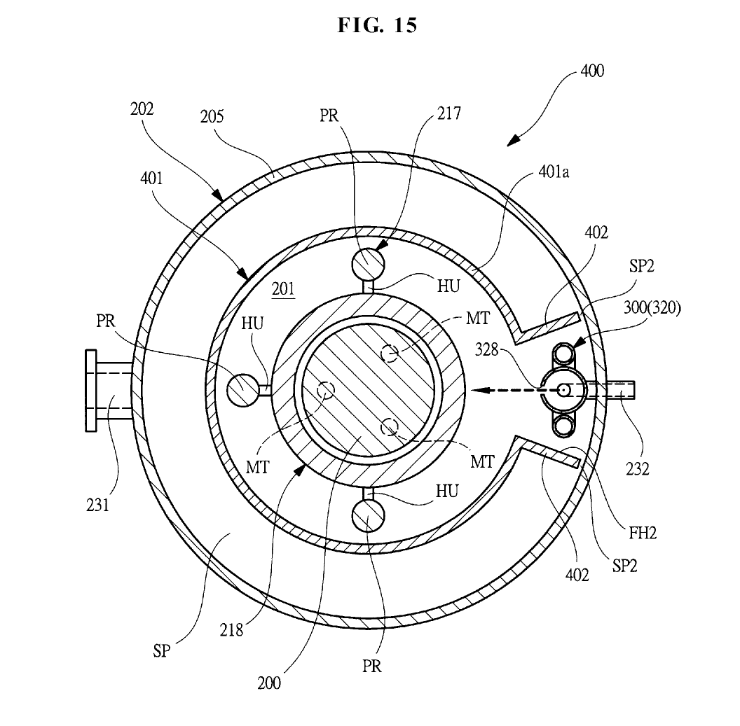

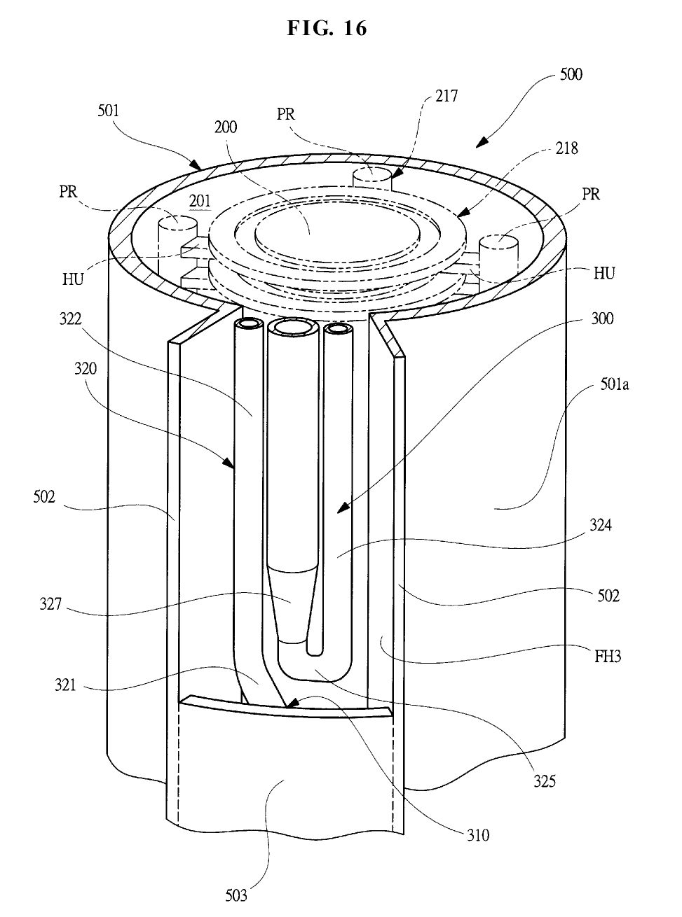

FIG. 15 is a longitudinal cross-sectional view illustrating a longitudinal section of a processing furnace of a substrate processing apparatus according to a second embodiment.

As shown in FIG. 15, a substrate processing apparatus 400 of the second embodiment is different from that of the first embodiment in an aspect of the shape of the inner tube 401. An opening FH2 is formed in a sidewall 401a of the inner tube 401 to allow communication between a processing chamber 201 in the inner tube 401 and a gap SP disposed outside the inner tube 401. The opening FH2 is formed by a pair of facing walls 402 protruding outward from a radial direction of the inner tube 401, and a base end side (or a left side of FIG. 15) of each of the facing walls 402 is connected to the sidewall 401a to be formed integrally with the sidewall 401a.

A front end side (or a right side of FIG. 15) of each of the facing walls 402 faces an inner wall of an outer tube 205, and a fine gap SP2 is formed between the front end side of each of the facing walls 402 and the outer tube 205. Thus, the opening FH2 allows the processing chamber 201 to communicate with the gap SP via each of the fine gaps SP2.

Here, the sum of opening areas of the respective fine gaps SP2 is set to be approximately equal to the opening area of the opening FH according to the first embodiment. Thus, similar to the substrate processing apparatus 101 according to the first embodiment, a gas supplied to the inner tube 230 is not easily leaked out of the inner tube 230, thus inhibiting wasteful consumption of a gas.

A width dimension of the opening FH2 in a circumferential direction of wafers 200 is set to be greater than that of a coiled pipe unit 310 of a gas supply nozzle 300 in the circumferential direction of the wafers 200. Thus, the gas supply nozzle 300 is disposed not to come in contact with either of the facing walls 402 inside the opening FH2. Also, the opening FH2 is formed in the entire axial region of the inner tube 401 and disposed not to come in contact with each of the facing walls 402 inside the opening FH2 even in an L-shaped pipe unit 310 (refer to FIGS. 11 and 12) of the gas supply nozzle 300.

<Representative Effects of Second Embodiment>

According to the technical idea described in the second embodiment, at least one of a plurality of effects described below can be obtained in addition to the effects (1) to (8) of the first embodiment.

(1) According to the second embodiment, since the gas supply nozzle 300 may be directly disposed opposite each susceptor 218 rather than disposed via the inner tube 230, the heating efficiency of a gas circulating inside the gas supply nozzle 300 may be further improved. Accordingly, for example, a gas circulation path of the gas supply nozzle 300 may be shortened so that the gas supply nozzle 300 can be miniaturized to enable downscaling of the substrate processing apparatus 400.

(2) Since each of the facing walls 402 is installed in the inner tube 401, a gas supplied to the inner tube 401 is not as easily out of the inner tube 401 to the gap SP. Thus, formation of a film on an inner wall of the outer tube 205 may be suppressed.

(3) By applying the substrate processing apparatus 400 described in the second embodiment to a substrate processing process of a method of fabricating a substrate, a method of processing a substrate has at least one of the plurality of effects mentioned above.

(4) By applying the substrate processing apparatus 400 described in the second embodiment to a substrate processing process of a method of fabricating a semiconductor device, the method of fabricating the semiconductor device has at least one of the plurality of effects mentioned above.

(5) By applying the substrate processing apparatus 400 described in the second embodiment to a substrate processing process of a method of fabricating a solar cell, the method of fabricating the solar cell has at least one of the plurality of effects mentioned above.

### Third Embodiment

Hereinafter, a substrate processing apparatus according to a third embodiment of the present invention will be described in detail with reference to the drawings. The same reference numerals are used to denote components having the same functions as in the second embodiment, and a detailed description thereof will be omitted.

FIG. 16 is a perspective view illustrating a configuration of an inner tube of a substrate processing apparatus according to a third embodiment.

As shown in FIG. 16, a substrate processing apparatus 500 of the third embodiment is different from that of the second embodiment in that a closing wall 503 for closing an opening FH3 is installed in an axial lower portion of an inner tube 501 (at a lower side of FIG. 16). A section of the closing wall 503 is formed in an arc shape to have a predetermined radius of curvature and is installed at a constant distance from the outer tube 205 (not shown). The closing wall 503 is integrally installed with a front end side (or just in front of a middle portion of FIG. 16) of each of facing walls 502 integrally installed with a sidewall 501a of the inner tube 501. A length dimension of the closing wall 503 in the axial direction of the inner tube 501 is set to be a dimension by which the closing wall 503 may face an L-shaped pipe unit 310 of a gas supply nozzle 300 in a radial direction. That is, the closing wall 503 is installed in an “adiabatic region” (refer to FIG. 11) that is not easily heated by either susceptor 218 of a processing furnace 202 (not shown).

<Representative Effects of Third Embodiment>

According to the technical idea described in the third embodiment, at least one of a plurality of effects described below can be obtained in addition to the effects (1) to (8) of the first embodiment and the effect (1) of the second embodiment.

(1) According to the third embodiment, a gas supplied to the processing chamber 201 may be precluded from coming into contact with a lower portion of the outer tube 205. Thus, formation of a film on an inner wall of the lower portion of the outer tube 205 may be suppressed. Thus, a maintenance (e.g., removal of a film) period of the outer tube 205 may be delayed, and an operation time of the substrate processing apparatus 500 may be increased. In addition, since the closing wall 503 may prevent a gas supplied to the inner tube 501 from leaking out of the inner tube 501, wasteful consumption of the gas may be inhibited more effectively.

(2) By applying the substrate processing apparatus 500 described in the third embodiment to a substrate processing process of a method of fabricating a substrate, a method of processing a substrate has at least one of the plurality of effects mentioned above.

(3) By applying the substrate processing apparatus 500 described in the third embodiment to a substrate processing process of a method of fabricating a semiconductor device, the method of fabricating the semiconductor device has at least one of the plurality of effects mentioned above.

(4) By applying the substrate processing apparatus 500 described in the third embodiment to a substrate processing process of a method of fabricating a solar cell, the method of fabricating the solar cell has at least one of the plurality of effects mentioned above.

### Fourth Embodiment

Hereinafter, a substrate processing apparatus according to a fourth embodiment of the present invention will be described in detail with reference to the drawings. The same reference numerals are used to denote components having the same functions as in the third embodiment, and a detailed description thereof will be omitted.

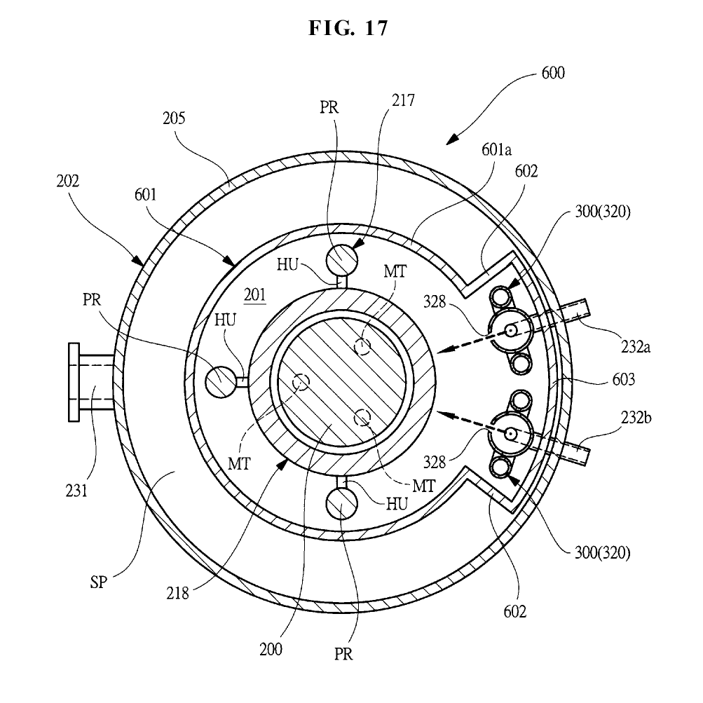

FIG. 17 is a longitudinal cross-sectional view illustrating a longitudinal section of a processing furnace of a substrate processing apparatus according to a fourth embodiment.

As shown in FIG. 17, a substrate processing apparatus 600 of the fourth embodiment is different from that of the second embodiment in that a closing wall 603 having an arc-type sectional shape is installed in an entire axial direction of the inner tube 601 to close an opening, a distance between facing walls 602 installed on a sidewall 601a in a circumferential direction of wafers 200, is increased, and two gas supply nozzles 300 are disposed between the facing walls 602. A gas supply hole 328 of each of the gas supply nozzles 300 disposed between the respective facing walls 602 is installed toward the center of the wafer 200 (or a susceptor 218). Different kinds of gases are supplied through the respective gas supply nozzles 300 to the wafers 200, and the respective gases supplied through the gas supply nozzles 300 are mixed in a processing chamber 201. For example, SiHCl₃ gas is supplied as a source gas through a gas supply pipe 232a corresponding to one of the gas supply nozzles 300, while H₂ gas is supplied as a carrier gas through a gas supply pipe 232b corresponding to the other of the gas supply nozzles 300.

<Representative Effects of Fourth Embodiment>

According to the technical idea described in the fourth embodiment, at least one of a plurality of effects described below can be obtained in addition to the effects (1) to (8) of the first embodiment, the effect (1) of the second embodiment, and the effect (1) of the third embodiment.

(1) According to the fourth embodiment, since the closing wall 603 is installed on the entire axial region of the inner tube 601, gas supplied to the processing chamber 201 may be prevented from contacting an inner wall of an outer tube 205. Accordingly, formation of a film on the inner wall of the outer wall 205 may be inhibited, a maintenance period of the outer tube 205 may be delayed, and an operation time of the substrate processing apparatus 600 may be increased. In addition, since the closing wall 603 may prevent a gas supplied to the inner tube 601 from leaking out of the inner tube 601, wasteful consumption of the gas may be inhibited more effectively.

(2) According to the fourth embodiment, since the two gas supply nozzles 300 are installed and configured to mix different gases in the processing chamber 201, formation of a film in each of the gas supply nozzles 300 may be suppressed. Accordingly, clogging of each of the gas supply nozzles 300 may be inhibited, a maintenance period of the outer tube 205 may be delayed, and the operation time of the substrate processing apparatus 600 may be increased.

(3) By applying the substrate processing apparatus 600 described in the fourth embodiment to a substrate processing process of a method of fabricating a substrate, a method of processing a substrate has at least one of the plurality of effects mentioned above.

(4) By applying the substrate processing apparatus 600 described in the fourth embodiment to a substrate processing process of a method of fabricating a semiconductor device, the method of fabricating the semiconductor device has at least one of the plurality of effects mentioned above.

(5) By applying the substrate processing apparatus 600 described in the fourth embodiment to a substrate processing process of a method of fabricating a solar cell, the method of fabricating the solar cell has at least one of the plurality of effects mentioned above.

### Fifth Embodiment

Hereinafter, a substrate processing apparatus according to a fifth embodiment of the present invention will be described in detail with reference to the drawings. The same reference numerals are used to denote components having the same functions as in the first embodiment, and a detailed description thereof will be omitted.

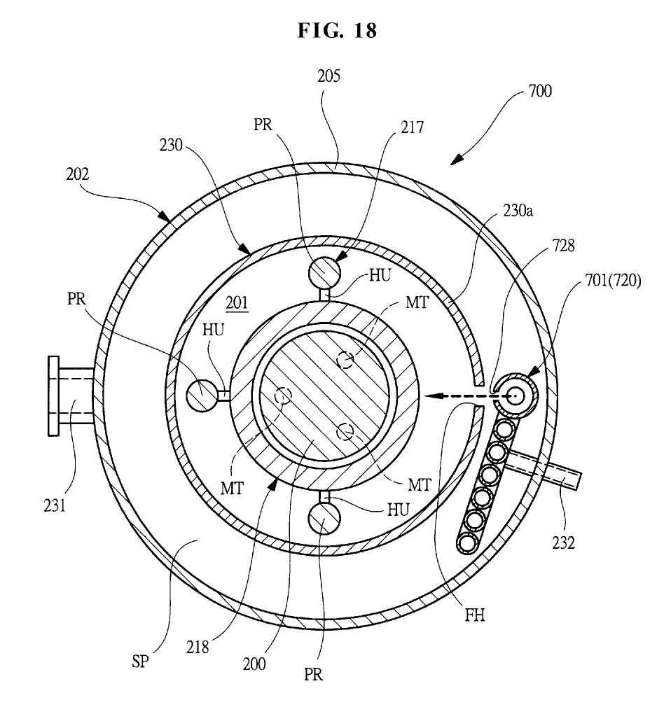

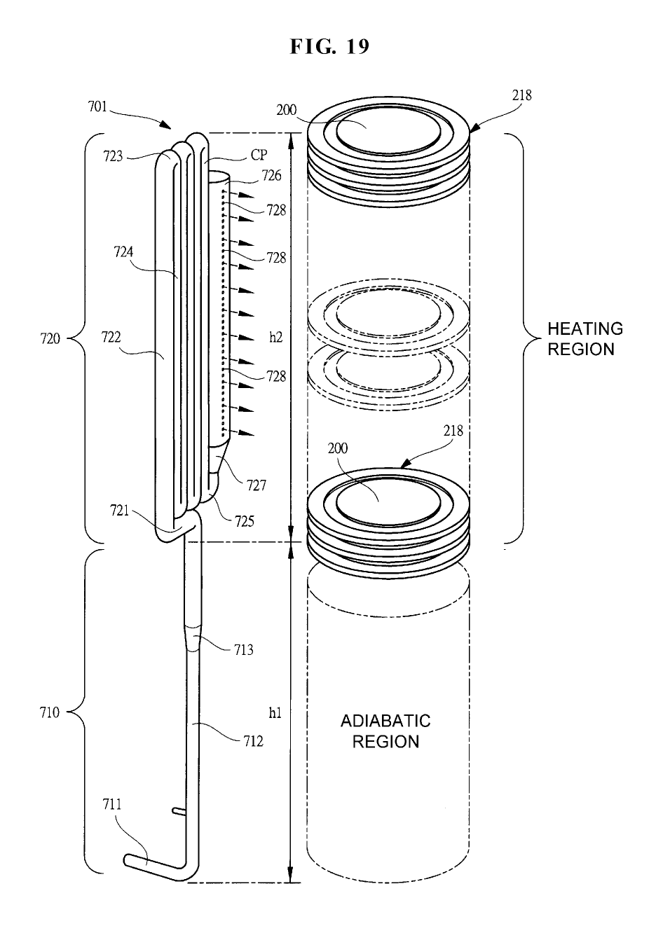

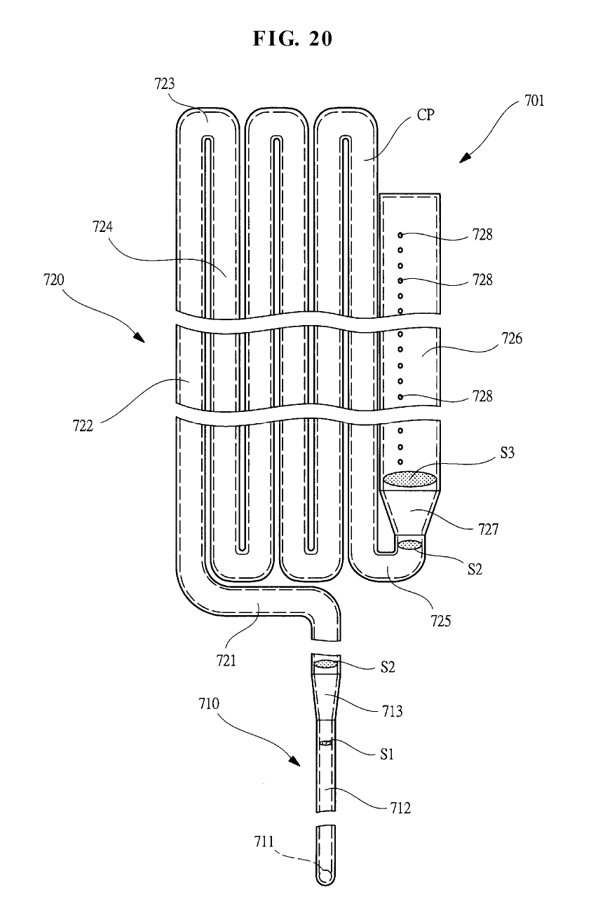

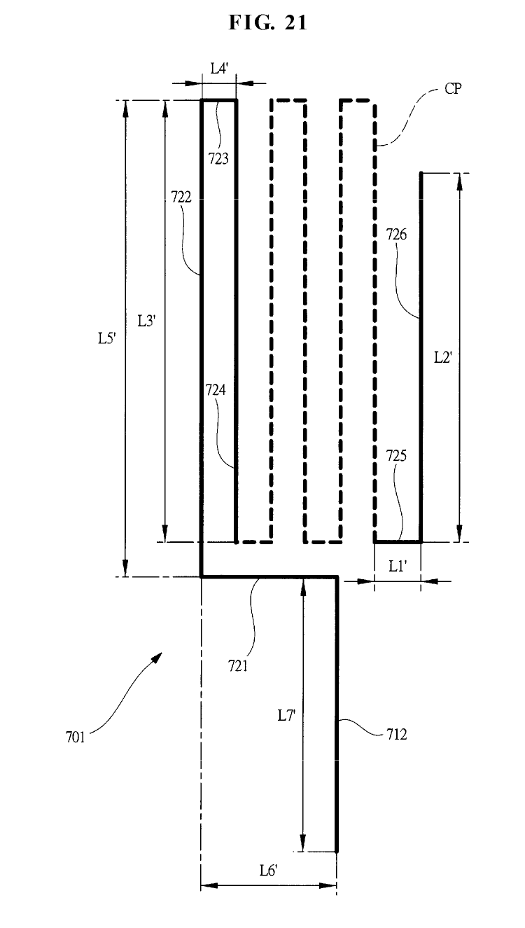

FIG. 18 is a longitudinal cross-sectional view illustrating a longitudinal section of a processing furnace of a substrate processing apparatus according to a fifth embodiment. FIG. 19 is a perspective view showing a positional relationship between a gas supply nozzle and a wafer according to the fifth embodiment. FIG. 20 is a lateral view of a detailed structure of the gas supply nozzle of FIG. 19. FIG. 21 is a diagram for explaining a pipe length of each portion of the gas supply nozzle of FIG. 20.

As shown in FIGS. 18 through 21, a substrate processing apparatus 700 of the fifth embodiment is different from that of the first embodiment in an aspect of the shape of a gas supply nozzle 701. The gas supply nozzle 701 includes an L-shaped pipe unit 710 forming a base end side and a zigzag pipe unit 720 forming a front end side. Similar to the L-shaped pipe unit 310 (refer to FIG. 11) of the first embodiment, the L-shaped pipe unit 710 is disposed in an “adiabatic region” having a height h1 that is not easily heated by each susceptor 218 of the processing furnace 202. Also, similar to the coiled pipe unit 320 (refer to FIG. 11) of the first embodiment, the zigzag pipe unit 720 is disposed in a “heating region” having a height h2 that may be uniformly heated by each of the susceptors 218 of the processing furnace 202.

The L-shaped pipe unit 710 includes a connector 711 extending in a radial direction of the processing furnace 202 and having one end connected to a gas supply pipe 232, and a base end (or a seventh pipe) 712 having a lower end connected to the other end of the connector 711 and extending in an axial direction of the processing furnace 202, that is, in a stacking direction of wafers 200. As shown in FIG. 21, a pipe length (length dimension) of the base end 712 is set to be L7′, which is approximately equal to the height h1 of the adiabatic region (refer to FIG. 19) of the processing furnace 202.

As shown in FIGS. 19 and 20, a first channel area adjusting unit 713 for gradually increasing the channel area of a pipe is installed in a roughly central portion of a rectangular (or lengthwise) direction of the base end 712 from the lower end of the base end 712 toward an upper end thereof. As can be seen from a crossed line part of FIG. 20, the first channel area adjusting unit 713 increases a channel area of the base end 712 from S1 to S2 (S1<S2). Thus, a flow velocity of a gas flowing toward the zigzag pipe unit 720 may be reduced, thereby improving heating efficiency of a gas (or facilitating the heating of the gas) in the zigzag pipe unit 720.

As shown in FIGS. 20 and 21, the zigzag pipe unit 720 includes a first extension part (or a sixth pipe) 721, a second extension part (or a fifth pipe) 722, a third extension part (or a fourth pipe) 723, a fourth extension part (a third pipe) 724, a zigzag unit CP, a fifth extension part (or a first pipe) 725, and a sixth extension part (or a second pipe) 726 from the side of the base end 712 of the L-shaped pipe unit 710.

The first extension part 721 extends toward a left portion of the drawing from the base end 712, that is, extends in a circumferential direction of the wafers 200. The other end (or a right end of the drawing) of the first extension part 721 is connected to the upper end of the base end 712, and a pipe length of the first extension part 721 is set to be L6′ (L6′<L7′).

The second extension part 722 extends toward an upper portion of the drawing from the first extension part 721, that is, extends in a stacking direction of the wafers 200, which is parallel to the base end 712. The other end (or a lower end of the drawing) of the second extension part 722 is connected to one end (or a left end of the drawing) of the first extension part 721, and a pipe length of the second extension part 722 is set to be L5′ (L5′>L6′).

The third extension part 723 extends toward a right portion of the drawing from the second extension part 722, that is, extends in the circumferential direction of the wafers 200 perpendicular to the base end 712. The other end (or a left end of the drawing) of the third extension part 723 is connected to one end (or an upper end of the drawings) of the second extension part 722, and a pipe length of the third extension part 723 is set to be L4′ (L4′<L5′).

The fourth extension part 724 extends toward a lower portion of the drawing from the third extension part 723, that is, extends in the stacking direction of the wafers 200, which is parallel to the base end 712. The other end (or the upper end of the drawing) of the fourth extension part 724 is connected to one end (or a right end of the drawing) of the third extension part 723, and a pipe length of the fourth extension part 724 is set to be L3′ (L3′>L4′). Also, the pipe length L3′ of the fourth extension part 724 is set to be shorter than the pipe length L5′ of the second extension part 722 (L3′<L5′), and at least portions of the fourth and second extension parts 724 and 722 have such a positional relationship as to overlap each other in the circumferential direction of the wafers 200. Thus, interference between the fourth and first extension parts 724 and 721 may be prevented.

The zigzag unit CP is denoted by a dotted line of FIG. 21. The zigzag unit CP is alternately connected to the third extension part 723 having the pipe length L4′ and the fourth extension part 724 having the pipe length L3′, and formed in a zigzag shape by performing U-turns a plurality of times. The other end (or the left end of the zigzag unit CP) of the zigzag unit CP is connected to one end (or the lower end of the drawing) of the fourth extension part 724. Also, the number of times the zigzag unit CP U-turns may be optionally determined. For example, the number of times the zigzag unit CP U-turns may be determined in consideration of a size (refer to FIG. 18) of a gap SP between an inner tube 230 and an outer tube 205 or an extent to which a temperature of a gas circulating in the gas supply nozzle 701 has risen.

The fifth extension part 725 extends toward the right portion of the drawing from the zigzag unit CP, that is, extends in the circumferential direction of the wafers 200 perpendicular to the base end 712. The other end (or the left end of the drawing) of the fifth extension part 725 is connected to one end (or the right end of the drawing) of the zigzag unit CP, and a pipe length of the fifth extension part 725 is set to be L1′ (L1′<L3′). Also, the pipe length L1′ of the fifth extension part 725 is set to be equal to the pipe length L4′ of the third extension part 723 (L1′ L4′). The fifth and sixth extension parts 725 and 723 have such a positional relationship as not to overlap each other in the stacking direction of the wafers 200.

The sixth extension part 726 extends toward the upper portion of the drawing from the fifth extension part 725, that is, extends in the stacking direction of the wafers 200, which is parallel to the base end 712. One end (or the lower end of the drawing) of the sixth extension part 726 is connected to one end (or the right end of the drawing) of the fifth extension part 725, and a pipe length of the sixth extension part 726 is set to be L2′ (L2′>L1′). Also, the pipe length L2′ of the sixth extension part 726 is set to be shorter than the pipe length L3′ of the fourth extension part 724 (L2′<L3′). At least portions of the sixth and fourth extension parts 726 and 724 have such as positional relationship as to overlap each other in the circumferential direction of the wafers 200.

Here, a pipe axis of the base end 712 is installed in an approximately central portion of the zigzag pipe unit 720 in the circumferential direction of the wafers 200. Thus, when the connector 711 is connected to the gas supply pipe 732, the gas supply nozzle 701 is stably supported by the base end 712. That is, rather than being inclined, the gas supply nozzle 701 may be supported to be straight. Furthermore, positional deviation of the gas supply nozzle 701 due to oscillation or instability of a gas supply position may be suppressed.

As shown in FIG. 20, a second channel area adjusting unit 727 for gradually increasing the channel area of a pipe is installed at one end (or the lower end of FIG. 20) of the sixth extension part 726 from a lower end of the sixth extension part 726 toward an upper end thereof. As can be seen from the crossed line part of FIG. 20, the second channel area adjusting unit 727 increases a channel area of the sixth extension part 726 from S2 to S3 (S1<S2<S3). Thus, a pressure of a gas in the sixth extension part 726 may be easily uniformized, thus uniformizing a flow rate of a gas supplied from a plurality of gas supply holes 728 installed in the sixth extension part 726 toward the wafers 200. In addition, the first extension part 721, the second extension part 722, the third extension part 723, the fourth extension part 724, the zigzag unit CP, and the fifth extension part 725 are set to have substantially the same channel area S2.

The other end (or the upper end of the drawing) of the sixth extension part 726 is closed, and the plurality of gas supply holes 728 are formed in a row in an axial direction of the sixth extension part 726 in a portion where the channel area of the sixth extension part 726 is set to be S3. Each of the gas supply holes 728 is formed in a circular shape to supply a gas from the outside of the processing furnace 202 to each of the wafers 200 stacked in the boat 217 in a horizontal direction. In addition, a size relationship among a diameter dimension of each of the gas supply holes 728, a width dimension of the opening FH (refer to FIG. 18) installed in a sidewall 230a of the inner tube 230, and an outer diameter dimension of the sixth extension part 726, and a positional relationship between each of the gas supply holes 728 and each of the wafers 200 (each of the susceptors 218) are the same as in the first embodiment. Here, the gas supply nozzle 701 may be applied to the second or fourth embodiment shown in FIGS. 15 through 17, instead of the gas supply nozzle 300.

<Representative Effects of Fifth Embodiment>

According to the technical idea described in the fifth embodiment, at least one of a plurality of effects described below can be obtained in addition to the effects (1) to (10) of the first embodiment.

(1) According to the fifth embodiment, the zigzag unit CP of the zigzag pipe unit 720 extends in the circumferential direction of the wafer 200. Thus, a gas circulation path of the gas supply nozzle 701 may be increased without reducing the pipe length L2′ of the sixth extension part 726. Accordingly, as compared with the gas supply nozzle 300 of the first embodiment, the gas supply nozzle 701 may be applied to various substrate processing apparatuses, thereby improving general usability of the gas supply nozzle 701.

(2) By applying the substrate processing apparatus 700 described in the fifth embodiment to a substrate processing process of a method of fabricating a substrate, a method of processing a substrate has at least one of the plurality of effects mentioned above.

(3) By applying the substrate processing apparatus 700 described in the fifth embodiment to a substrate processing process of a method of fabricating a semiconductor device, the method of fabricating the semiconductor device has at least one of the plurality of effects mentioned above.

(4) By applying the substrate processing apparatus 700 described in the fifth embodiment to a substrate processing process of a method of fabricating a solar cell, the method of fabricating the solar cell has at least one of the plurality of effects mentioned above.

While the embodiments of the invention conducted by the present inventors have been particularly described above, the present invention is not limited to the embodiments set forth and it will be understood by those of ordinary skill in the art that various changes in form and details may be made therein without departing from the scope of the present invention. For example, while the embodiments of the present invention have been explained using an epitaxial apparatus, the technical idea of the present invention may be applied to other substrate processing apparatuses, such as a CVD apparatus, an ALD apparatus, an oxidation apparatus, a diffusion apparatus, or an annealing apparatus.

Furthermore, while the embodiments have described that the disk-type susceptor 218 is used as a heated body, a plurality of rod-shaped susceptors (or heated bodies to be induced) may be installed between the outer tube 205 and the inner tube 230, 401, 501, or 601. Alternatively, the disk-type susceptor 218 may be replaced by the inductive heating apparatus 206 disposed in an outer circumference of the outer tube 205, and a resistive heated body of a resistive heating system may be installed.

What is claimed is:

1. A substrate processing apparatus comprising:
a reaction container configured to process a plurality of substrates stacked in a substrate holder;
a heated body configured to heat an inside of the reaction container; and
a gas nozzle installed in the reaction container, and including a first pipe extending in a circumferential direction of the plurality of substrates and a second pipe including a gas supply hole wherethrough a gas supplied from an outside of the reaction container is supplied in a horizontal direction with respect to each of the plurality of substrates stacked on the substrate holder, the second pipe extending in a stacking direction of the plurality of substrates and having a first end connected to a first end of the first pipe.

2. The apparatus of claim 1, wherein the gas nozzle further comprises:
a third pipe having a first end connected to a second end of the first pipe and extending in the stacking direction of the plurality of substrates are; and
a fourth pipe having a first end connected to a second end of the third pipe and extending in the circumferential direction of the plurality of substrates.

3. The apparatus of claim 2, wherein the first pipe and the fourth pipe are installed at a first end side and a second end side of the stacking direction of the plurality of substrates, respectively.

4. The apparatus of claim 1, wherein a plurality of the heated bodies are stacked on the substrate holder in a manner that each of the plurality of the heated bodies holds each of the plurality of substrates, and
the first pipe and the second pipe of the gas nozzle are installed in a region where the plurality of the heated bodies are stacked in the stacking direction of the plurality of substrates.

5. The apparatus of claim 1, wherein the first pipe and the second pipe are installed in a region where the heated bodies uniformly heats the inside of the reaction container.

6. The apparatus of claim 1, wherein a gas channel area of the second pipe is greater than that of the first pipe.

7. The apparatus of claim 2, wherein the fourth pipe is longer than the first pipe, and at least a portion of the first pipe is located to overlap the fourth pipe in the stacking direction of the plurality of substrates.

8. The apparatus of claim 2, wherein the third pipe is longer than the second pipe, and at least a portion of the second pipe is located to overlap the third pipe in the circumferential direction of the plurality of substrates.

9. The apparatus of claim 2, wherein the gas nozzle further comprises a fifth pipe having a first end connected to a second end of the fourth pipe and extending in the stacking direction of the plurality of substrates,
wherein the fourth pipe is longer than the first pipe, the third pipe is longer than the second pipe, and the fifth pipe is longer than the third pipe.

10. The apparatus of claim 9, wherein the gas nozzle further comprises:
a sixth pipe having a first end connected to a second end of the fifth pipe and extending in the circumferential direction of the plurality of substrates; and
a seventh pipe having a first end connected to a second end of the sixth pipe and extending coaxially with the second pipe in the stacking direction of the plurality of substrates.

11. The apparatus of claim 2, further comprising an inner tube installed in the reaction container, the inner tube including a gas flowing hole disposed opposite to the gas supply hole of the gas nozzle and,
wherein a width of the gas flowing hole in the circumferential direction of the plurality of substrates is such that the inner tube covers at least a portion of the third pipe.

12. The apparatus of claim 1, further comprising an inner tube installed in the reaction container, the inner tube including a gas flowing hole disposed opposite to the gas flowing hole of the gas nozzle and,
wherein a width of the gas flowing hole in the circumferential direction of the plurality of substrates is smaller than that of the second pipe in the circumferential direction of the plurality of substrates, and greater than that of the gas supply hole in the circumferential direction of the plurality of substrates.

13. The apparatus of claim 2, wherein a portion of the gas nozzle has a zigzag shape.

14. The apparatus of claim 2, wherein the gas nozzle further comprises a fifth pipe having a first end connected to a second end of the fourth pipe and extending in the stacking direction of the plurality of substrates, and
the first pipe and the fourth pipe are of a same length and disposed not to overlap each other in the stacking direction of the plurality of substrates, the third pipe is longer than the second pipe, and the third pipe and the fifth pipe are of a same length and disposed to at least partially overlap each other in the circumferential direction of the plurality of substrates.

15. A substrate processing apparatus comprising:
a reaction container having a cylindrical shape and configured to process substrates stacked and held in a plurality of stages in a substrate holder in a lengthwise direction of the substrate holder;
a heated body configured to heat an inside of the reaction container; and
a gas nozzle installed in the reaction container, and including a base end part extending from a lower end of the reaction container to a lower portion of a substrate holding region of the substrate holder, a first extension part having a second end connected to an upper end of the base end and extending in a circumferential direction of the substrate, a second extension part having a second end connected to a first end of the first extension part and extending in a stacking direction of the substrates, a third extension part having a second end connected to a first end of the second extension part and extending in the circumferential direction of the substrate, a fourth extension part having a second end connected to a first end of the third extension part and extending in the stacking direction of the substrates, a fifth extension part having a second end connected to a first end of the fourth extension part and shorter than the third extension part and extending in the circumferential direction of the substrate, and a sixth extension part having a gas supply hole configured to supply a gas in a horizontal direction to the substrates stacked and held in the plurality of stages in the substrate holder, the sixth extension part having a first end connected to a first end of the fifth extension part and extending in the stacking direction of the substrates.

16. The apparatus of claim 15, further comprising a channel area adjusting unit installed at each of the base end and the sixth extension part of the gas nozzle to increase a channel area thereof.

17. A method of processing a substrate, comprising:
conveying a plurality of substrates stacked in a substrate holder to an inside of a reaction container; and
supplying gas to each of the plurality of substrates through a gas supply hole of a gas nozzle, the gas supply hole being configured to supply a gas in a horizontal direction from an outside of the reaction container to each of the plurality of substrates stacked in the substrate holder, and the gas nozzle being installed in the reaction container and including at least a first pipe extending in a circumferential direction of the substrate, and a second pipe extending in a stacking direction of the plurality of substrates and having a first end connected to a first end of the first pipe, and processing each of the plurality of substrates while heating the first pipe, the second pipe, the gas, and the plurality of substrates using a heated body configured to heat the inside of the reaction container.
